(19) United States
(12) Patent Application Publication
(10) Pub. No.: US 2026/0285302 A1
(43) Pub. Date: Sep. 24, 2026

(54) SYSTEM AND METHOD FOR MITIGATING MACHINE COLLISIONS ALONG PASSAGEWAYS

(71) Applicant: Caterpillar Inc., Peoria, IL (US)

(72) Inventors: Maung Thant Zin Shein, Bulleen (AU); Jonathan Rafferty, Pascoe Vale (AU); Jyoti Prakash Mishra, Glenroy (AU); Brij Raj, Craigieburn (AU)

(73) Assignee: Caterpillar Inc., Peoria, IL (US)

(21) Appl. No.: 19/570,254

(22) Filed: Mar. 18, 2026

(30) Foreign Application Priority Data
Mar. 18, 2025 (KR) 10-2025-0034792

(51) Int. Cl. B60W 30/09; B60W 30/095; B60W 50/14

(52) U.S. Cl. CPC B60W 30/09; B60W 30/095; B60W 2050/143; B60W 2300/17; B60W 2420/408; B60W 2540/18; B60W 2552/50; B60W 2554/801; B60W 2554/802; B60W 2720/10

(57) ABSTRACT

A system for mitigating machine collision in a passageway comprises a machine, remote sensing system, and a controller in communication with the machine and the remote sensing system. The controller monitors a current speed and a steering angle or rate of the machine and determines, via the remote sensing system, a clearance of the machine with sidewall(s) of the passageway. The controller also determines a stopping distance of the machine. Further, the controller creates virtual safety zone(s) that dynamically extend longitudinally and laterally from the machine in real-time based on a monitored environment by the remote sensing system, the current speed, the steering angle or rate, the stopping distance, and the clearance. The controller also performs at least one action when the remote sensing system detects an incursion and/or an obstacle in the virtual safety zone(s) and/or when the clearance is less than at least one threshold clearance.

### TECHNICAL FIELD

The present disclosure relates, in general, to preventing machine collisions. More particularly, the present disclosure relates to a system and a method for mitigating machine collisions along passageways.

### BACKGROUND

Underground worksites, such as mining tunnels and subterranean construction zones, often involve movement of machines including loaders, haul trucks, and drilling rigs through narrow passageways such as underground tunnels. These passageways typically have irregular geometries, sharp turns, and limited visibility, which significantly increase a risk of the machines colliding with side walls or at blind corners. Such collisions can lead to undesirable consequences, including structural damage to the tunnel, equipment downtime, costly repairs, and potential injury to operators or personnel in proximity. Challenges in navigating such passageways by the machines are further exacerbated by environmental factors such as poor lighting, dust accumulation, rockfalls or rockslides, and water seepage, which impair visibility, machine traction, and machine movement. Additionally, a confined nature of underground passageways restricts maneuverability, thereby causing difficulty in maintaining safe clearance from walls, especially when machines operate at varying speeds or while carrying heavy loads. Conventional safety systems, which rely primarily on operator vigilance or proximity sensors, often fail to provide adequate protection in these complex environments due to latency in operator response or inability to account for dynamic changes in tunnel geometry. In some instances, a performance and accuracy of output(s) of such sensors is also compromised due to sensor damage or due to the challenging environment within the passageways. Existing solutions focus on surface-level operations or open environments where Global Positioning System (GPS)-based navigation and wide-area sensing are feasible. However, underground conditions limit effectiveness of such technologies because GPS signals are unavailable, and sensor performance can degrade due to dust, moisture, and reflective surfaces.

US patent 9594376, herein referred to as the “US ’376 reference”, discloses a method for driving a mining and/or construction machine arranged to be controlled by an operator by means of maneuvering means. The method of the US ’376 reference comprises, estimating a path that has been requested by said operator by means of steering commands, determining whether said machine when moving according to said requested path will be driven within a first distance from a first obstacle present in the environment, and when said machine, when travelling along said path, will be driven within a first distance from said first obstacle, influencing the path of said machine by means of a control system. However, the method taught in the US ’376 reference is insufficient to overcome all the above stated challenges in navigating the machine through narrow passageways or in mitigating collision of the machine due to factors such as the dynamic changes in the tunnel geometry.

### SUMMARY

In an aspect of the present disclosure, a system for mitigating machine collision in a passageway is disclosed. The system includes a machine configured to operate in the passageway. The system also includes at least one remote sensing system configured to monitor an environment of the passageway in front of and along the direction of movement of the machine, detect a presence of an obstacle in the monitored environment, and detect a proximity of at least one lateral side of the machine to at least one side wall of the passageway. Further, the system also includes a controller in communication with the machine and configured to control a movement of the machine in the passageway. The controller is configured to monitor a current speed of the machine and a steering angle or a steering rate of the machine defined by an input device in communication with the controller during the movement of the machine. Further, the controller is also configured to determine an estimated distance the machine is expected to travel after a braking action is performed to bring the machine to a halt based on the monitored current speed. The controller is also configured to determine an estimated clearance between the at least one lateral side of the machine with the at least one side wall of the passageway based on the detected proximity by the remote sensing system, the monitored steering angle or steering rate of the machine, or a combination thereof. Further, the controller is configured to create at least one virtual safety zone that dynamically extends longitudinally along the direction of movement of the machine and laterally from each lateral side of the machine in real-time based on the monitored environment by the remote sensing system, the monitored current speed, the estimated distance, and the estimated clearance. The at least one virtual safety zone extends longitudinally along a length of the machine and up to the estimated distance or beyond the estimated distance and up to a maximum detected distance in the passageway by the remote sensing system. The lateral extension of the at least one virtual safety zone dynamically varies based on the estimated clearance. In addition, the controller is configured to perform at least one action when the remote sensing system detects the obstacle in at least one of the plurality of safety zones, the estimated clearance is less than at least one threshold clearance, or any combination thereof.

In another aspect, a controller for mitigating machine collision in a passageway is disclosed. The controller includes a processor and a memory for storing instructions that, when executed by the processor, causes and/or configures the processor to receive at least one input from at least one remote sensing system. The at least one remote sensing system is configured to monitor an environment of the passageway in front of and along the direction of movement of the machine, detect a presence of an obstacle in the monitored environment, and detect a proximity of at least one lateral side of the machine to at least one side wall of the passageway. The processor is also configured to monitor a current speed of the machine and a steering angle or a steering rate of the machine defined by an input device in communication with the processor during the movement of the machine. Further, the processor is also configured to determine an estimated distance the machine is expected to travel after a braking action is performed to bring the machine to a halt based on the monitored current speed. The processor is also configured to determine an estimated clearance between the at least one lateral side of the machine with the at least one side wall of the passageway based on the detected proximity by the remote sensing system, the monitored steering angle or steering rate of the machine, or a combination thereof. Further, the processor is configured to create at least one virtual safety zone that dynamically extends longitudinally along the direction of movement of the machine and laterally from each lateral side of the machine in real-time based on the monitored environment by the remote sensing system, the monitored current speed, the estimated distance, and the estimated clearance. The at least one virtual safety zone extends longitudinally along a length of the machine and up to the estimated distance or beyond the estimated distance and up to a maximum detected distance in the passageway by the remote sensing system. The lateral extension of the at least one virtual safety zone dynamically varies based on the estimated clearance. In addition, the processor is configured to perform at least one action when the remote sensing system detects the obstacle in at least one of the plurality of safety zones and the at least one received input is indicative of the detected obstacle, the estimated clearance is less than at least one threshold clearance, or any combination thereof.

In yet another aspect, a method for mitigating machine collision in a passageway is disclosed. The method includes receiving, via a controller, at least one input from a remote sensing system of a machine. The at least one input comprises a monitored environment of the passageway in front of and along the direction of movement of the machine, an indication of a presence of an obstacle in the monitored environment, a proximity of at least one lateral side of the machine to at least one side wall of the passageway, or any combination thereof. The method also includes monitoring, via the controller, a current speed of the machine and a steering angle or a steering rate of the machine defined by an input device in communication with the controller during the movement of the machine. Further, the method includes determining, via the controller, an estimated distance the machine is expected to travel after a braking action is performed to bring the machine to a halt based on the monitored current speed. In addition, the method includes determining, via the controller, an estimated clearance between the at least one lateral side of the machine with the at least one side wall of the passageway based on the detected proximity by the remote sensing system, the monitored steering angle or steering rate of the machine, or a combination thereof. Furthermore, the method includes creating, via the controller, at least one virtual safety zone that dynamically extends longitudinally along the direction of movement of the machine and laterally from each lateral side of the machine in real- time based on the monitored environment by the remote sensing system, the monitored current speed, the estimated distance, and the estimated clearance. The at least one virtual safety zone extends longitudinally along a length of the machine and up to the estimated distance or beyond the estimated distance and up to a maximum detected distance in the passageway by the remote sensing system. The lateral extension of the at least one virtual safety zone dynamically varies based on the estimated clearance. The method also includes performing, via the controller, at least one action when the remote sensing system detects an obstacle in at least one of the plurality of safety zones and the at least one received input is indicative of the detected obstacle, the estimated clearance is less than at least one threshold clearance, or any combination thereof.

### BRIEF DESCRIPTION OF DRAWINGS

FIG. 1 is an illustration of an exemplary environment including an exemplary system for mitigating machine collision in a passageway, in accordance with the embodiments of the present disclosure;

FIG. 2 is an illustration of an exemplary machine employed in the exemplary environment of FIG. 1, in accordance with the embodiments of the present disclosure;

FIG. 3 is an illustration of an exemplary remote operator station (ROS) including an exemplary controller, an exemplary steering input device, and an exemplary output device employed in the environment of FIG. 1 for managing the steering of the exemplary machine of FIG. 2, in accordance with the embodiments of the present disclosure;

FIG. 4 is a block diagram of an exemplary controller employed in the exemplary environment of FIG. 1, in accordance with the embodiments of the present disclosure;

FIGS. 5 and 6 are exemplary illustrations of the exemplary controller of FIG. 4 determining actual and estimated clearance(s) of one or more lateral sides of the exemplary machine of FIG. 2 with one or more side walls of the passageway of FIG. 1, in accordance with the embodiments of the present disclosure;

FIG. 7 is an illustration of exemplary virtual safety zones created by the exemplary controller of FIGS. 1 and/or 4 along the direction of movement of the machine in the passageway, in accordance with the embodiments of the present disclosure;

FIGS. 8, 9, and 10 are illustrations of exemplary modifications in a shape of the at least one virtual zone by the exemplary controller of FIGS. 1 and/or 4 based on an articulation of the machine, in accordance with the embodiments of the present disclosure;

FIG. 11 is an illustration of exemplary longitudinal extensions of the exemplary virtual safety zone(s) of FIG. 7 created by the exemplary controller of FIGS. 1 and/or 4, in accordance with the embodiments of the present disclosure;

FIGS. 12 and 13 are illustrations of exemplary lateral extensions of the exemplary virtual safety zone(s) of FIG. 7 created by the exemplary controller of FIGS. 1 and/or 4 corresponding to a change in clearance between at least one lateral side of the machine and at least one side wall of the passageway, in accordance with the embodiments of the present disclosure;

FIGS. 14 and 15 are illustrations of exemplary lateral extensions of the exemplary virtual safety zone(s) of FIG. 7 created by the exemplary controller of FIGS. 1 and/or 4 along only one lateral side of the machine, in accordance with the embodiments of the present disclosure;

FIGS. 16-18 are illustrations of exemplary longitudinal extensions and changes in visual representation of the exemplary virtual safety zone(s) of FIG. 7 created by the exemplary controller of FIGS. 1 and/or 4 corresponding to a longitudinal movement and approach of the machine towards a corner in the passageway, in accordance with the embodiments of the present disclosure;

FIGS. 19-22 are illustrations of exemplary lateral extensions and a change in visual representation of the exemplary virtual safety zone(s) of FIG. 7 created by the exemplary controller of FIGS. 1 and/or 4 from a lateral side of the machine corresponding to a lateral movement and approach of the machine towards a side wall of the passageway, in accordance with the embodiments of the present disclosure;

FIG. 23 is a block diagram of the exemplary machine of FIG. 2 employed in the exemplary environment of FIG. 1, in accordance with the embodiments of the present disclosure; and

FIG. 24 is a flowchart of an exemplary method for mitigating machine collision in a passageway, in accordance with the embodiments of the present disclosure.

### DETAILED DESCRIPTION

Reference will now be made in detail to specific embodiments or features, examples of which are illustrated in the accompanying drawings. Generally, corresponding reference numbers may be used throughout the drawings to refer to the same or corresponding parts, e.g., 1, 1`, 1``, 101 and 201 could refer to one or more comparable components used in the same and/or different depicted embodiments.

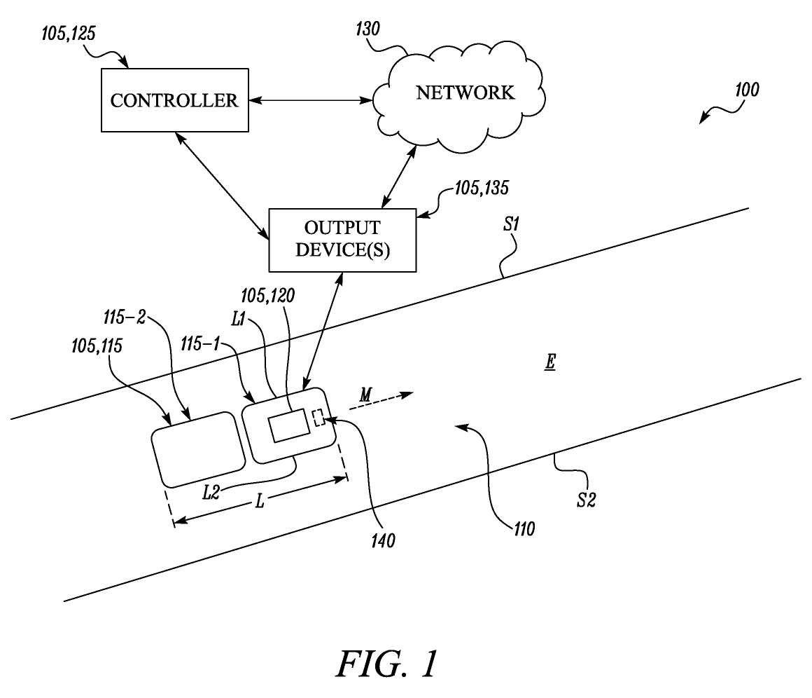

Referring to FIG. 1, an illustration of an environment 100, herein referred to as the ‘worksite 100’, including an exemplary system 105 for mitigating machine collisions in a passageway 110 provided within the worksite 100 is shown. Examples of the worksite 100 include, but are not limited to, underground mining sites, construction sites, or road laying sites including one or more narrow passageways, such as the passageway 110, for machine movement. In embodiments, the exemplary system 105 includes a machine 115, a remote sensing system 120, and a controller 125 in communication with each other via a network 130. Examples of the network 130 include, but are not limited to, a Local Area Network (LAN), a Wireless Local Area Network (WLAN), a Small Area Network (SAN), a Wi-Fi Direct Network, satellite network, low power long range network (LoRa), and a telecommunication network including, but not limited to, a fourth generation (4G) and a fifth generation (5G) cellular network. Examples of the machine 115 include, but are not limited to, an underground mining truck, an underground load-haul-dump (LHD) loader, a backhoe loader, a skid steer loader, a wheel loader, a material loader, a motor grader, a track- type tractor, a landfill compactor, an excavator, an articulated truck, or any other machine now known or later developed. In embodiments, the machine 115 is an articulated or a rigid machine. The articulated machine is a work machine defining two or more rigid sections or portions connected to each other by a pivoting joint or a coupling (not shown). The rigid machine is a work machine defining one or more sections or portions fixed onto a single chassis (not shown) of the rigid machine. In embodiments, the machine 115 operating within the passageway 110 defines a length L, and includes lateral sides, for example, L1 and L2 that define corresponding clearances, for example, C1 and C2 with the side wall(s), for example, S1 and S2 of the passageway 110. In embodiments, the remote sensing system 120 is mounted on and/or retrofitted to the machine 115. In embodiments, the remote sensing system 120 provided in the passageway 110 is also contemplated. In embodiments, the remote sensing system 120 is configured to monitor an environment ‘E’ of the passageway 110 in front of and along the direction of movement ‘M’ of the machine 115. Examples of the remote sensing system 120 include, but are not limited to, Light Detection and Ranging (LiDAR) or Laser Detection and Ranging (LADAR). In embodiments, the controller 125 is configured to remotely control a movement of the machine 115 in the passageway 110. Examples of the controller 125 include, but are not limited to, computers, laptops, mobile devices, handheld devices, personal digital assistants (PDAs), tablet personal computers, digital notebook, wearables, Electronic Control Units (ECUs), physical, cloud, and/or virtual servers, and other electronic devices known or later developed for performing functions consistent with the present disclosure.

In embodiments, the controller 125 is configured to remotely control the machine 115 via at least one steering input device (not shown). Examples of the at least one steering input device include, but are not limited to, a joystick, a keyboard, one or more keys or buttons, a touchscreen display device, or any other input device now known or later developed for performing functions consistent with the present disclosure. In embodiments, the controller 125 and the steering input device provided in a remote operator station (ROS) are also contemplated. In such embodiments, the steering input device is configured to receive one or more inputs from a remote-control operator, and the one or more received inputs are indicative of a direction, acceleration, and/or a steering movement to be implemented by the machine 115 in the passageway 110. The controller 125 is configured to translate the one or more received inputs to corresponding instructions to be provided to the machine 115. The controller 125 is then configured to provide the instructions to the machine 115 via the network 130 in order to control the movement of the machine 115 in the passageway 110 via the controller 125. In embodiments, the controller 125 provided in the machine 115 is also contemplated. In such embodiments, the controller 125 is configured to control the movement of the machine 115 corresponding to one or more steering inputs received, via a steering wheel (not shown) of the machine 115, from a field operator operating the machine 115 in the passageway 110.

In embodiments, the system 105 also includes one or more output devices 135 in communication with the controller 125 directly or via the network 130. In embodiments, the output device(s) 135 is configured to provide one or more alerts and/or alarms in response to the controller 125 determining, via the remote sensing system 120, a potential collision or an undesirable proximity of, for example, the lateral sides L1, L2 of the machine 115 to one or more side walls, for example, S1, S2 of the passageway 110, or a front end of the machine 115 to an obstacle detected in the passageway 110. Examples of the output devices 135 include, but are not limited to, a display device, one or more alert/alarm systems, one or more sound boxes/speakers, and one or more visual indicators. In embodiments, the output device(s) 135 coupled to the controller 125 and provided in a remote operator station (ROS) is contemplated. In embodiments, the output device(s) 135 provided at one or more locations within the passageway 110 is also contemplated. In embodiments, the output device(s) 135 provided in the machine 115 is also contemplated. In embodiments, the machine 115 also includes one or more monitoring devices 140 for capturing one or more machine inputs and/or monitoring one or more machine parameters associated with the machine 115 and providing the captured input(s) and/or the monitored parameter(s) to the controller 125. Examples of the one or more monitoring devices 140 include, but are not limited to, one or more inertial measurement units (IMUs), sensors including, but not limited to, thermal sensors, motion sensors, and vibration sensors, and one or more machine tracking devices including, but not limited to, one or more global positioning system (GPS) receivers, Radio-Frequency Identification (RFID) devices, and laser or light walls or screens. Examples of the one or more machine inputs include, but are not limited to, input(s) associated with a location, positioning, acceleration, direction of movement, and steering angle/rate of the machine.

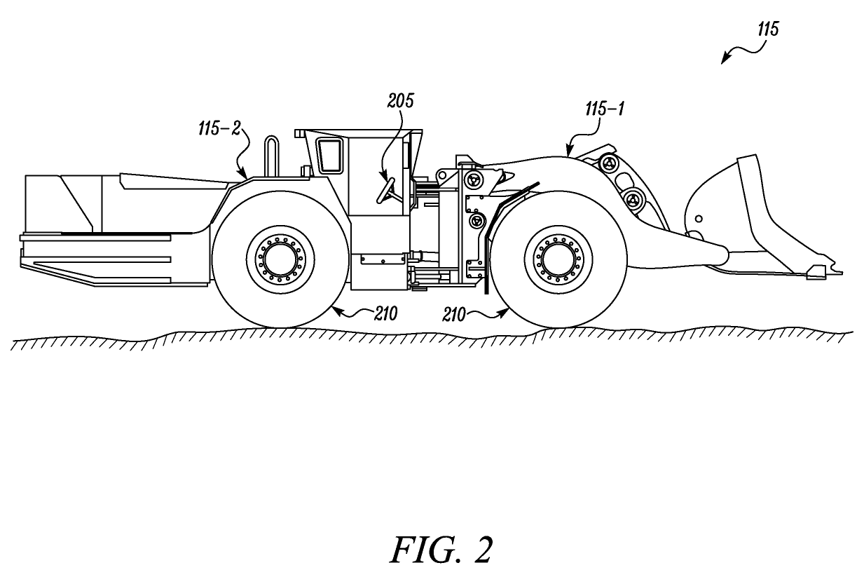

Referring to FIG. 2, an illustration of the exemplary machine 115 of FIG. 1 corresponding to, as an example, the underground LHD loader, including a steering wheel 205, wheels 210, and the remote sensing system 120 is shown. Although not illustrated it should be understood that, in embodiments, the machine 115 also includes the output device(s) 135 (see FIG. 1). In embodiments, the machine 115 defines a front machine section 115-1 and a rear machine section 115-2. In embodiments, the front machine section 115-1 is pivoted with respect to the rear machine section 115-2 such that, during a forward and lateral movement of the machine 115 along a curved path in the passageway 110, the front machine section 115-1 is configured to, first, turn laterally along the curved path followed by a pivoted movement of the rear-machine section 115-2 in the lateral direction. In embodiments, the machine 115 may be operated manually by an operator disposed in a cabin (not shown) provided in the machine 115 (“manual mode”). In embodiments, the machine 115 may also be operated remotely by an operator via the controller 125 (see FIG. 1) such that the operator is physically distanced from hazardous environments and relocated to a safe and/or secure location such as the remote operator station (ROS). In such embodiments, the operator is able to guide and control the machine 115 remotely via the controller 125 based on the captured input(s) and/or the monitored parameter(s) received from the monitoring device(s) 140 provided in the machine 115. In embodiments, the machine 115 may also be operated remotely by an operator using a remote-control device including, but not limited to, a mobile (e.g., handheld) device, for instances when the machine 115 is within a line of sight (LOS) of the operator. In embodiments, the machine 115 can also be operated semi-autonomously by a remote operator and/or the controller 125 based on the captured input(s) and/or the monitored parameter(s) by the monitoring device(s) 140. In such embodiments, the controller 125 is configured to autonomously control one or more predefined functions or operations of the machine 115. In embodiments, the machine 115 can also be operated fully autonomously by the controller 125 based on the captured input(s) and/or the monitored parameter(s) by the monitoring device(s) 140 provided in the machine 115. In such embodiments, the controller 125 is provided in the machine 115.

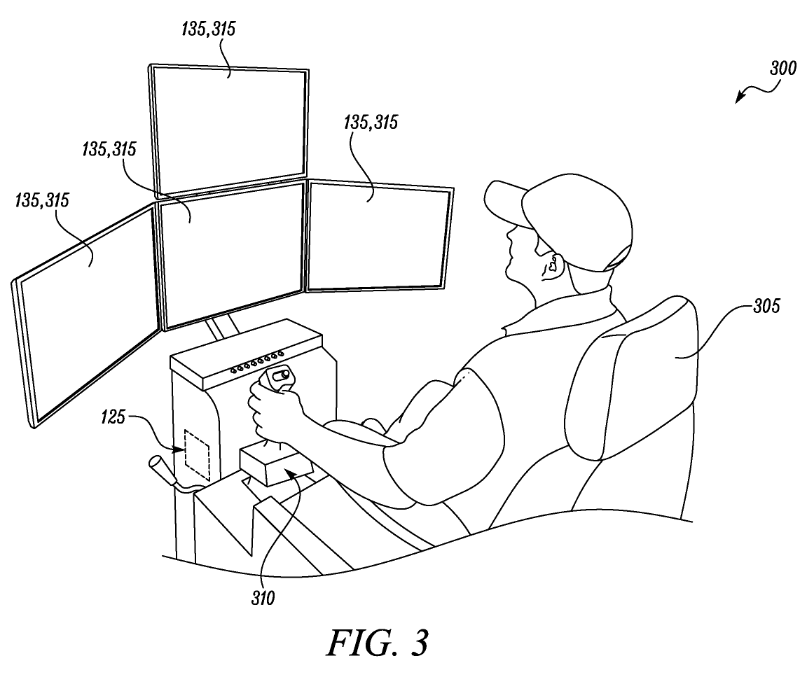

Referring to FIG. 3, an illustration of the exemplary remote operator station (ROS) 300 including an operator seat 305, the steering input device 310, the controller 125, and the output device(s) 135 is shown. In embodiments, the controller 125 is configured to assist the operator operating from the operator seat 305 to monitor the machine 115 operating at the worksite 100 via the output device 135 based on the captured input(s) and/or the monitored parameter(s) received from the monitoring device(s) 140 provided in the machine 115. In embodiments, the output device 135 is configured to provide the captured input(s) and/or the monitored parameter(s) via, for example, a display device 315. In embodiments, based on the monitoring, the controller 125 is also configured to assist the operator to remotely control a movement and/or steering of the machine 115 in the worksite 100 via the steering input device 310. In embodiments, the output device 135 is also configured to control a movement of the machine 115 in response to the movement of the steering input device 310 via the display device 315. For example, the controller 125 enables the operator to move the steering input device 310 and simultaneously view the movement of the machine 115 via the output device 135, i.e. the display device 315. In embodiments, the controller 125 is also configured to receive one or more steering inputs via the steering input device 310 to correspondingly steer the machine 115 within the worksite 100 and/or the passageway 110. Examples of the steering input(s) include, but are not limited to, a movement of the steering input device 310 corresponding to a joystick in one or more directions, a selection of one or more buttons (not shown) provided in the steering input device 310, a mouse input received via the steering input device 310 corresponding to a mouse (not shown) coupled with and in communication with the output device 135, a touchscreen input received via the steering input device 310 corresponding to the touchscreen interface of the display device 315, or any other type of input defining the movement and/or steering of the machine 115. In embodiments, the touchscreen input corresponds to a movement of a graphical user interface element including, but not limited to, one or more virtual joysticks provided in the display device 315. In embodiments, in response to receiving the steering input(s) via the steering input device 310, the controller 125 is also configured to provide one or more instructions to the machine 115 remotely via the network 130 and initiate the machine 115 to move or steer in a direction and/or a speed defined by the received steering input from the steering input device 310.

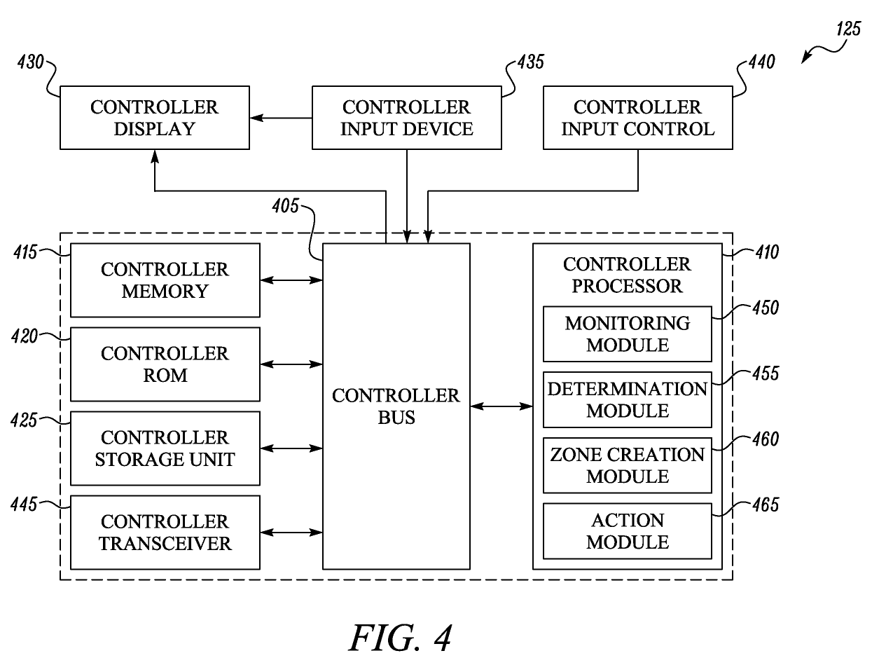

The various components of the controller 125 will now be described hereinafter with respect to FIG. 4. It should be appreciated by those of ordinary skill in the art that FIG. 4 depicts the controller 125 in a simplified manner and a practical embodiment includes additional components and suitably configured logic to support known or conventional operating features that are not described in detail herein. Although the controller 125 is illustrated and described as being implemented within a single device, it is contemplated that the one or more components of the controller 125 are alternatively implemented in a distributed computing environment.

Referring to FIG. 4, the controller 125 includes a controller bus 405 or other communication mechanism for communicating information, and a controller processor 410 coupled with the controller bus 405 for processing information. The controller 125 also includes a controller memory 415, such as a random-access memory (RAM) or other dynamic storage device, coupled to the controller bus 405 for storing information and instructions to be executed by the controller processor 410. The controller memory 415 can be used for storing temporary variables or other intermediate information during execution of instructions to be executed by the controller processor 410. The controller 125 further includes a controller read-only-memory (ROM) 420 or other static storage device coupled to the controller bus 405 for storing static information and instructions for the controller processor 410.

A controller storage unit 425, such as a magnetic disk, optical disk, or a solid- state disk, is provided and coupled to the controller bus 405 to store information. Examples of the information include, but are not limited to, a type of the exemplary machine 115 (see FIGS. 1 and 2), machine identification of the exemplary machine 115, information received from the monitoring device(s) 140 provided in the exemplary machine 115, a current steering angle and/or rate of the exemplary machine 115, and a current position and/or location of the exemplary machine 115 within the exemplary worksite 100 (see FIG. 1). It will be understood, by those with ordinary skill in the art, that the information stored in the controller storage unit 425 is accessed by the controller processor 410 via the controller memory 415 to perform one or more functions.

The controller 125 can be coupled via the controller bus 405 to the output device(s) 135 (see FIG. 1) including, but not limited to, a controller display 430, such as a light emitting diode (LED) and a liquid crystal display (LCD) for displaying information to an operator of the controller 125. A controller input device 435 is coupled to controller bus 405 for communicating information and command selections to the controller processor 410. The controller input device 435 may be included in the controller display 430, for example, a touch screen that facilitates detection of multi- touch inputs from the user via the controller display 430. The controller input device 435 may also correspond to peripheral input devices that may be paired with the controller 125 via Bluetooth, Wi-Fi, Wi-Fi direct, or as a hardware connection such a USB peripheral to the controller 125. Examples of the peripheral input devices include, but are not limited to, a remote-control joystick, a gamepad, a keyboard, a mouse, a gesture-controlled device, or a wearable device such as, for example, a smartwatch. In embodiments, the controller input device 435 may also correspond to a microphone (not shown) provided in the controller 125 that is configured to receive audio inputs or instructions from the operator(s) of the controller 125. In embodiments, the controller input device 435 may also include alphanumeric and other keys. Another type of user input device is a controller input control 440, such as a mouse, a trackball, or cursor direction keys for communicating direction information and command selections to the controller processor 410 and for controlling cursor movement on the controller display 430.

Various embodiments are related to the use of controller 125 for implementing the techniques described herein. In one embodiment, the techniques are performed by the controller 125 in response to the controller processor 410 executing instructions included in the controller memory 415. Such instructions can be read into the controller memory 415 from another machine-readable medium, such as the controller storage unit 425. Execution of the instructions included in the controller memory 415 causes the controller processor 410 to perform the process steps described herein.

The term “machine-readable medium” as used herein refers to any medium that participates in providing data that causes a machine to operate in a specific fashion. In an embodiment implemented using the controller 125, various machine-readable medium is involved, for example, in providing instructions to the controller processor 410 for execution. The machine-readable medium can be a storage media. Storage media includes both non-volatile media and volatile media. Non-volatile media includes, for example, optical, solid-state, or magnetic disks, such as the controller storage unit 425. Volatile media includes dynamic memory, such as the controller memory 415. All such media must be tangible to enable the instructions carried by the media to be detected by a physical mechanism that reads the instructions into a machine. Common forms of machine-readable medium include, for example, a floppy disk, a flexible disk, hard disk, magnetic tape, or any other magnetic medium, a CD-ROM, any other optical medium, punch cards, paper-tape, any other physical medium with patterns of holes, a RAM, a PROM, and EPROM, a FLASH-EPROM, any other memory chip, or cartridge.

In another embodiment, the machine-readable medium can be a transmission media including coaxial cables, copper wire, and fibre optics, including the wires that include the controller bus 405. Transmission media can also take the form of acoustic or light waves, such as those generated during radio-wave and infra-red data communications. In embodiments, the machine-readable medium corresponds to any other medium from which the controller 125 can read, for example, online software, download links, installation links, and online links. For example, the instructions can initially be carried on a magnetic disk of a remote computer. The remote computer can load the instructions into its dynamic memory and send the instructions over a telephone line using a modem. A modem local to the controller 125 can receive the data on the telephone line and use an infra-red transmitter to convert the data to an infra-red signal. An infra-red detector can receive the data carried in the infra-red signal and appropriate circuitry can place the data on the controller bus 405. The controller bus 405 carries the data to the controller memory 415, from which the controller processor 410 retrieves and executes the instructions. The instructions received by the controller memory 415 can optionally be stored in the controller storage unit 425 either before or after execution by the controller processor 410.

The controller 125 also includes a controller transceiver 445 coupled to the controller bus 405. The controller transceiver 445 provides a two-way data communication coupling with the exemplary machine 115, the monitoring device(s) 140 provided in the machine 115, the output device(s) 135, and/or the remote sensing system 120 via the network 130. In one example, the controller transceiver 445 can be an integrated service digital network (ISDN) card or a modem to provide a data communication connection to a corresponding type of telephone line. In another example, the controller transceiver 445 can be a local area network (LAN) card to provide a data communication connection to a compatible LAN. Wireless links can also be implemented. In any such implementation, the controller transceiver 445 sends and receives radio, electrical, electromagnetic, or optical signals that carry digital data streams representing various types of information.

In embodiments, the controller processor 410 may be capable of executing the computer instructions stored in the controller memory 415 to perform one or more functions. In embodiments, the controller processor 410 may include one or more modules 450-465 to perform the one or more functions. For example, the controller processor 410 may include a monitoring module 450, a determination module 455, a zone creation module 460, and an action module 465. It may be understood that the modules 450-465 may correspond to and/or include hardware and/or software components respectively and may be configured to perform respective functions.

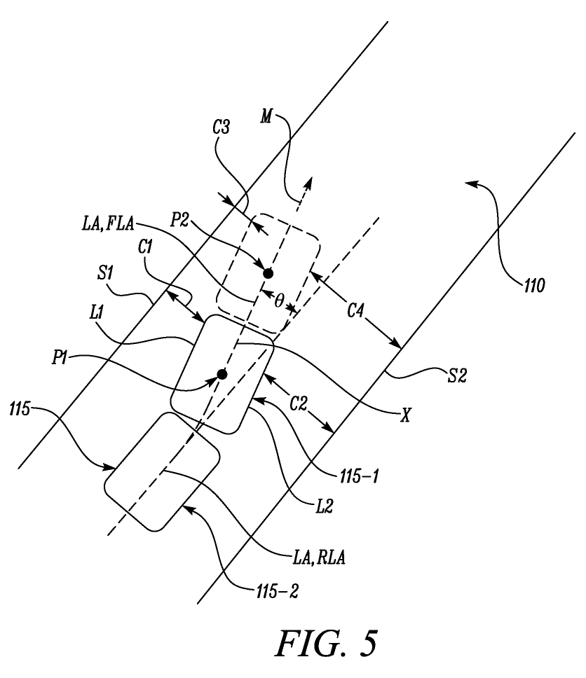

In embodiments, the monitoring module 450 is configured to monitor a current speed via the monitoring device(s) 140 and the network 130. In embodiments, the monitoring module 450 is also configured to monitor, via the steering input(s) received from the steering input device, for example, 310 (see FIG. 3), a steering angle or a steering rate of the machine 115 defined by the steering input device, for example, 310. The steering rate corresponds to an angular velocity at which front or rear wheels (not shown) of the machine 115 are to be turned corresponding to a position of the steering input device, for example, 310. In embodiments herein, the angular velocity is expressed in degrees per second. In other words, the steering rate is the rate of change of the steering angle associated with the front or rear wheels of the machine 115 corresponding to the position of the steering input device 310. The steering angle of the machine 115 corresponds to an angle at which the front or rear wheels of the machine 115 are turned relative to a longitudinal axis LA (see FIG. 5) of the machine 115. For instances when the machine 115 is an articulated machine, the steering angle corresponds to an articulation angle, for example, ϴ (see FIG. 5) defined between the longitudinal axis FLA (see FIG. 5) of the front machine section 115-1 (see FIG. 5) and the longitudinal axis RLA (see FIG. 5) of the rear machine section 115-2 (see FIG. 5) of the machine 115. In embodiments, the monitoring module 450 is configured to determine and/or account for a steering latency between the steering input(s) provided by the steering input device, for example, 310 and a corresponding steering action performed by the machine 115 in response to the steering input. The steering latency corresponds to an inherent time delay in translating the steering input(s) received by the steering input device, for example, 310 to the corresponding steering action performed by the machine 115. In embodiments, the steering input(s) define the steering rate or angle to be implemented by the machine 115 and the machine 115 performs the corresponding steering action of implementing the defined steering rate and/or angle after the time delay (i.e., the steering latency).

In embodiments, the monitoring module 450 is also configured to receive one or more remote sensing inputs from the remote sensing system 120 (see FIG. 1) provided in the machine 115 via the network 130. Examples of the remote sensing input(s) include, but are not limited to, point cloud or spatial data associated with the environment ‘E’ (see FIG. 1) of the passageway 110 (see FIG. 1), a proximity of one or more side walls, for example, S1, S2 (see FIG. 1) of the passageway 110 to one or more lateral sides, for example, L1, L2 (see FIG. 1) of the machine 115, and one or more obstacles including, but not limited to, a blind corner, debris, narrow turns, and boulders in the passageway 110 along the direction of movement ‘M’ of the machine 115. In embodiments, the monitoring module 450 is configured to generate a 3- dimensional (3D) view of the environment ‘E’ of the passageway 110 in front of and along the direction of movement ‘M’ (see FIG. 1) of the machine 115 in the passageway 110 based on the remote sensing input(s). In embodiments, the monitoring module 450 is also configured to provide the generated 3D view via the controller display 430.

In embodiments, the determination module 455 is configured to locate and/or identify one or more side walls, for example, S1, S2 of the passageway 110 based on the one or more received remote sensing input(s) including, for example, the generated 3D view and/or the determined proximity of the side wall(s), for example, S1, S2 by the monitoring module 450. In embodiments, the determination module 455 is configured to determine a current clearance, for example, C1, C2 (see FIG. 1) and/or an estimated clearance between the at least one lateral side, for example, L1, L2, of the machine 115 and the at least one side wall, for example, S1, S2 of the passageway 110 based on the detected proximity by the remote sensing system 120, the generated 3D view, and/or the monitored steering angle or steering rate of the machine.

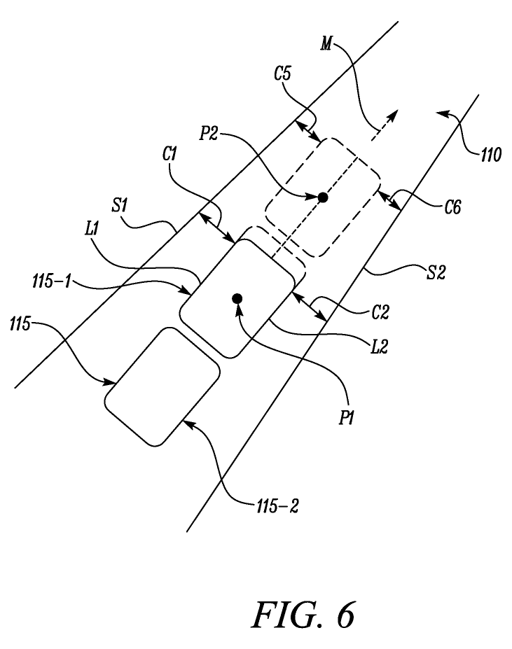

As an example, referring to FIGS. 5 and 6, exemplary illustrations of the determination module 455 determining the current and estimated clearance between the at least one lateral side, for example, L1, L2, of the machine 115 and the at least one side wall, for example, S1, S2 of the passageway 110 is shown. In embodiments, the determination module 455 is configured to determine the current clearance, for example, C1, C2, between the at least one lateral side, for example, L1 and the at least one side wall, S1 of the passageway 110 based on a current position, for example, P1 of the machine 115 in the passageway 110 with respect to the at least one side wall, for example, S1. Similarly, as another example, the determination module 455 is configured to predict a future position, for example, P2 of the machine 115 from the current position, for example, P1 of the machine 115 based on the monitored steering angle and/or steering rate of the machine and determine the estimated clearance, for example, C3, C4 of the machine 115 based on the predicted future position, for example, P2. In embodiments, the determination module 455 is configured to determine the estimated clearance, for example, C3, C4 prior to the machine 115 approaching the at least one side wall, for example, S1 and moving to a new position, for example, P2 from a current position, for example, P1 of the machine 115 based on the monitored steering rate and/or angle ϴ. In embodiments, the determination module 455 is configured to determine the estimated clearance, for example, C3, C4 within an estimated time lag between a time instance at which a steering input including the steering angle ϴ and/or rate is defined by the steering input device 310 (see FIG. 3) and an actual time instance at which the machine 115 initiates the steering movement in response to the steering input received from the steering input device 310. As yet another example, the determination module 455 is configured to determine the estimated clearance, for example, C5, C6 and/or a continuous change in the estimated clearance and/or the actual clearance, for example, C1, C2 based on a change in the monitored environment including, but not limited to, a narrowing or widening of the passageway 110 along the direction of movement ‘M’ of the machine 115.

Referring again to FIG. 3, in embodiments, the determination module 455 is also configured to determine an estimated distance the machine 115 is expected to travel after a braking action is performed to bring the machine 115 to a halt based on the monitored current speed. In embodiments, the estimated distance corresponds to and is herein referred to as the “stopping distance” of the machine 115. In embodiments, the determination module 455 is also configured to determine a running distance the machine 115 is expected to travel from a first time instance of receiving the braking action to halt the machine 115 via the steering input device 310 to a second time instance of the machine 115 initiating the braking action to halt the machine 115 in order to determine the stopping distance of the machine 115. In embodiments, the determination module 455 is also configured to determine an actual distance travelled by the machine 115 until halt after the initiation of the braking action by the machine 115. In embodiments, the determined stopping distance by the determination module 455 is equal to a sum of the determined running distance and the determined actual distance. For instances when the machine 115 is manually operated, for example, by an operator, the determination module 455 is also configured to determine the running distance the machine 115 is expected to travel based on an estimated operator reaction time duration taken by the operator to initiate the braking action in order to bring the machine 115 to a halt.

In embodiments, the zone creation module 460 is configured to create at least one virtual safety zone that dynamically extends longitudinally along the direction of movement ‘M’ of the machine 115 and laterally from each lateral side, for example, L1, L2 of the machine 115 in real-time based on the monitored environment by the remote sensing system 120, the monitored current speed, the determined stopping distance, the determined actual clearance, for example, C1, C2 (see FIGS. 5 and 6), and/or the estimated clearance, for example, C3, C4, C5, C6 (see FIGS. 5 and 6). In embodiments, the at least one virtual safety zone extends longitudinally along the length L (see FIG. 1) of the machine 115 and up to the determined stopping distance and/or beyond the determined stopping distance and up to a predefined distance or a maximum detected distance in the passageway 110 by the remote sensing system 120.

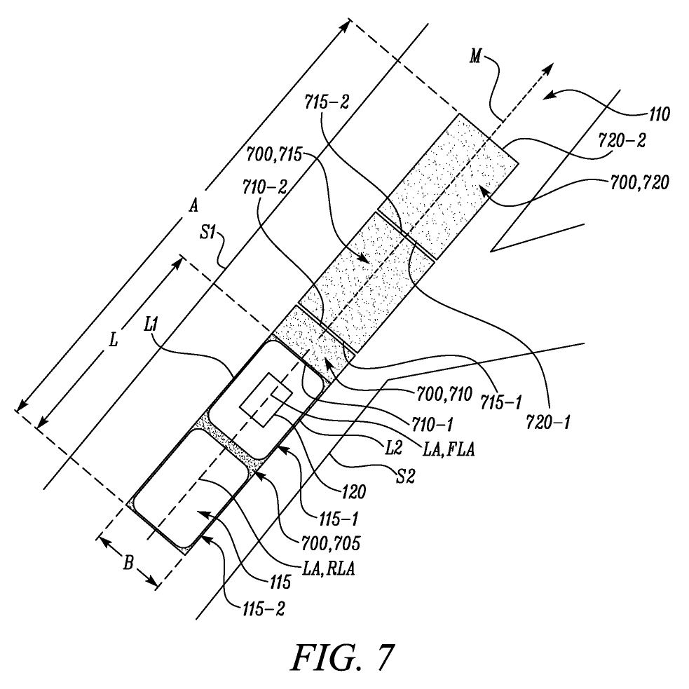

As an example, referring to FIG. 7, an exemplary illustration of the at least one virtual safety zone 700 and/or the longitudinal extension A of the at least one virtual safety zone 700 created by the zone creation module 460 (see FIG. 4) is shown. In embodiments, the at least one created virtual safety zone 700 extends longitudinally beyond the determined stopping distance, for example, 715-2 and up to a predefined distance or a maximum detected distance, for example, 720-2 in the passageway 110 by the remote sensing system 120. In embodiments, the at least one created virtual safety zone 700 extends along the length L of the machine 115 and up to the maximum detected distance, for example, 720-2 in the passageway 110 by the remote sensing system 120. In embodiments, the at least one created virtual safety zone 700 includes first, second, third, and fourth virtual safety zones, for example, 705, 710, 715, and 720 respectively. In embodiments, the zone creation module 460 is configured to create the first virtual safety zone 705 extending longitudinally along the length L of the machine 115. In embodiments, the zone creation module 460 is configured to create the first virtual safety zone, for example, 705 to account for one or more collision factors associated with the machine 115. Examples of the collision factors include, but are not limited to, reaction time of operator in the remote operator station (ROS) 300 when the machine 115 is remote-controlled, or within the machine 115 when the machine 115 is manually operated, and delay or time lag (i.e., the steering latency) between receiving steering inputs from the steering input device 310 by the controller 125 and the machine 115 consequently responding to the steering inputs received from the controller 125 by, for example, applying the braking action or reducing the current speed of the machine 115. In embodiments, the zone creation module 460 is also configured to create the second virtual safety zone 710 extending longitudinally from a frontal end 710-1 of the machine 115 to a threshold buffer distance, for example, 710-2. In embodiments, the threshold buffer distance corresponds to an additional safety distance provided as a buffer in the at least one virtual safety zone 700 to minimize a possibility of the machine 115 colliding with the side walls S1, S2 and/or an object detected in the at least one zone 700 when the machine 115 is to be stopped or halted abruptly. In embodiments, the zone creation module 460 is also configured to create the third virtual safety zone 715 extending longitudinally after a threshold buffer distance, for example, 710-2 and starting at 715-1 ahead of the machine 115 up to the determined stopping distance, for example, 715-2. In embodiments, the zone creation module 460 is configured to create the fourth virtual safety zone 720 extending beyond the determined stopping distance, for example, 715-2, and starting at 720-1 and up to the maximum detected distance, for example, 720-2 in the passageway 110 by the remote sensing system 120. In embodiments, the at least one virtual safety zone 700 created by the zone creation module 460 extends longitudinally up to a total length or distance that is equal to a sum of the length L of the machine 115 and corresponding distances of first, second, third, and fourth virtual safety zones, for example, 705, 710, 715, 720 from the machine 115. In embodiments, the total length or distance of the at least one virtual safety zone 700 corresponds to the longitudinal extension A of the at least one virtual safety zone 700.

In embodiments herein, the zone creation module 460 is also configured to dynamically modify a shape of the at least one virtual safety zone 700 based on one or more articulation factors including, but not limited to, a current steering angle of the machine 115, current position, for example, P1 (see FIGS. 5 and 6) of the machine 115 in the passageway 110, a projected future position, for example, P2 (see FIGS. 5 and 6) of the machine 115 in the passageway 110 based on the current position and the current steering angle, historic data associated with the current position and/or the projected position of the machine 115, the remote sensing inputs received from the remote sensing system 120, a current and/or projected path, for example, X1, X2, X3 of the movement of the machine 115 based on the current steering angle, the steering latency, or any other factor associated with the movement of the machine 115 within the passageway 110. For example, the zone creation module 460 is configured to create the at least one virtual safety zone 700 in a rectangular shape for instances when the machine 115 is moving linearly along a straight path in the passageway 110. Similarly, the zone creation module 460 is configured to warp or curve the rectangular shape of the at least one virtual safety zone 700 in response to a change in the current steering angle of the machine away from a linear path, for example, when the longitudinal axis FLA of the front machine section 115-1 of the machine 115 is angled, for example, by the articulation angle ϴ from the longitudinal axis RLA of the rear machine section 115-2. In embodiments, the zone creation module 460 is configured to create irregular shapes of the at least one virtual safety zone 700 based on the one or more articulation factors.

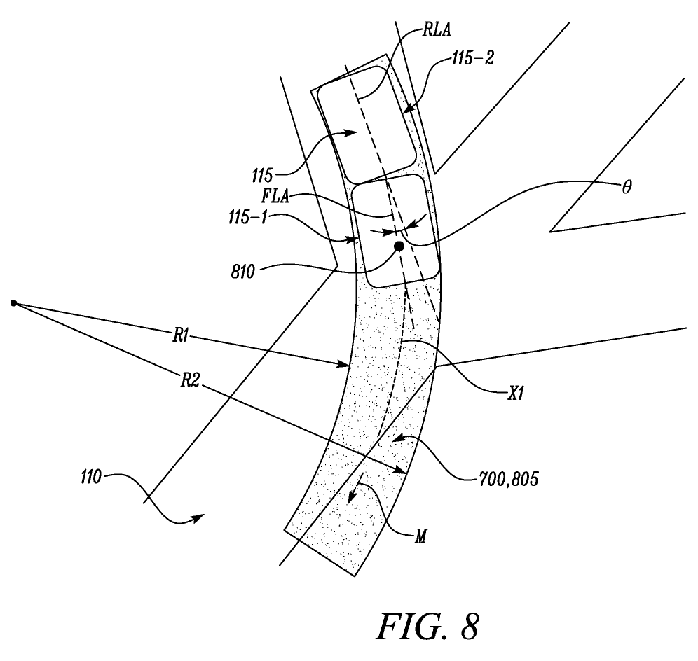

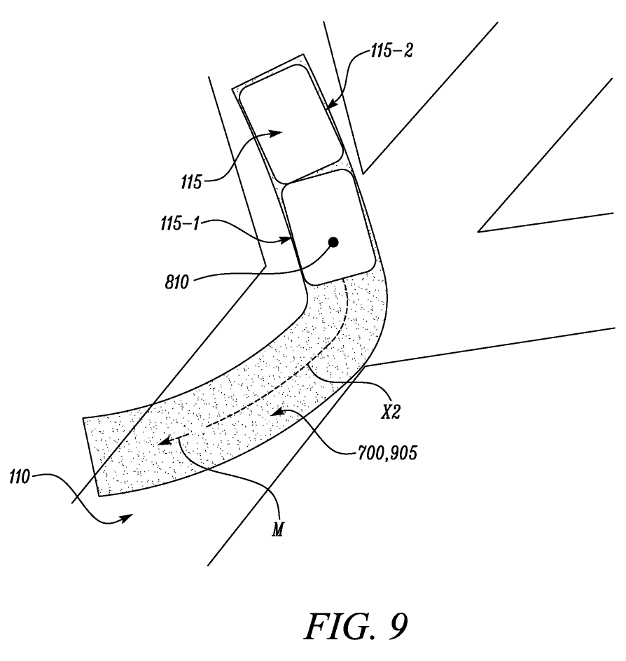

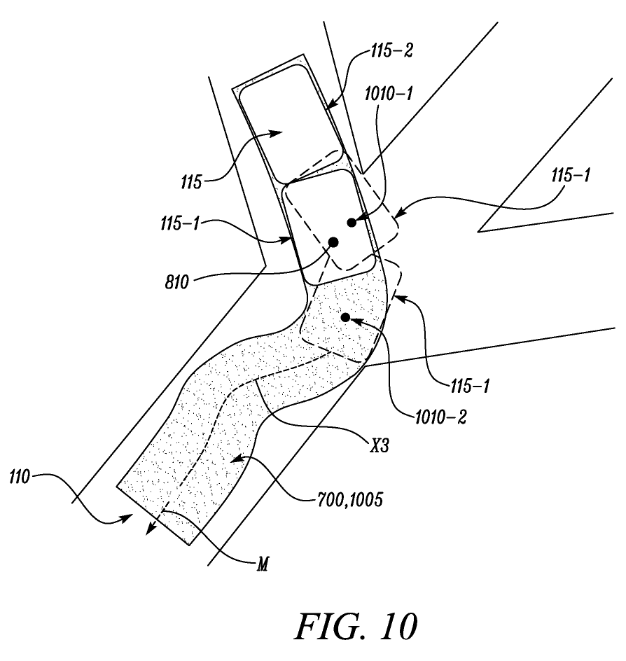

For example, referring to FIGS. 8-10, illustrations of exemplary modifications in the shape of the at least one virtual zone 700 created by the zone creation module 460 are shown. In embodiments, as shown in FIG. 8, the zone creation module 460 is configured to determine the current steering and/or articulation angle of the machine 115 and create the virtual safety zone 700, 805 based on the current position, for example, 810 and/or the current path, for example, X1 by warping the rectangular shape of the at least one virtual safety zone 700 such that the warped rectangular shape of the at least one safety zone 700 defines a first curving radius R1 and a second curving radius R2. In embodiments, the zone creation module 460 is also configured to further dynamically modify the warping of the rectangular shape of the virtual safety zone 700, 805 to create the virtual safety zone 700, 905 as shown in FIG. 9 based on the historic data, the current path X1, the projected path, for example, X2 of the machine, and previously defined curved radii, for example, the first curving radius R1, the second curving radius R2. Examples of the historic data include, but are not limited to, previously defined and/or recorded steering speeds and/or angles corresponding to the current path and/or the projected path of the machine 115 by the machine 115, previously recorded paths, for example, X3 traversed by the machine 115 in the passageway 110 corresponding to the current position 805 and/or the predicted future position, for example, 1010-1, 1010-2 of the machine 115, or any other historic data associated with the machine 115 and/or the passageway 110. In embodiments, the zone creation module 460 is configured to determine the current path X1 and/or the projected path X2 by implementing one or more navigation techniques. Examples of the one or more navigation techniques include, but are not limited to, dead reckoning, or any other navigation technique now known or later developed. The dead reckoning is a navigation technique that calculates the current position, for example, 810 of the machine 115 by projecting a last known position (not shown) of the machine 115 using the current speed, the direction of movement M, the current steering angle, and/or an elapsed time since the last past position of the machine 115. In embodiments, the zone creation module 460 is configured to further modify the warped rectangular shape of the machine 115 of the virtual safety zone 700, 905 to create the virtual safety zone 700, 1005 having the irregular shape as shown in FIG. 10 based on the predicted position, for example, 1010-1 and 1010-2 of the machine 115 from the current position 810, the historic data, and the projected path, for example, X3 of the machine 115 based on the historic data. In embodiments, the zone creation module 460 is configured to create the virtual safety zone 700, 1005 by determining steering angle requirements of the machine 115 corresponding to the each predicted future position, for example, 1010-1 and 1010-2 based on the remote sensing input(s) from the remote sensing system 120 (see FIG. 1) and determining the projected path, for example, X3, based on the determined steering angle requirements. It may also be understood that for instances when the zone creation module 460 determines that the predicted future position, for example, 1010-1 and 1010-2 and/or the predicted path(s), for example, X2, X3 is different from an actual position and/or path of the machine 115 in the passageway 110 after an estimated time duration, the zone creation module 460 is configured to dynamically adapt the shape of the at least one virtual safety zone 700 (see FIG. 7) based on the one or more articulation factors. For example, the zone creation module 460 is configured to retain the warped or curved shape of the virtual safety 700, 805 in such instances.

In embodiments, the zone creation module 460 is also configured to dynamically vary the longitudinal extension A of the at least one virtual safety zone 700 along the direction of movement M of the machine 115 based on one or more longitudinal zone extension factors including, but not limited to, the current speed, the determined stopping distance of the machine 115, the maximum detected distance of the remote sensing system 120 of the machine 115, a reaction time of the operator manually operating the machine 115 in minimizing the current speed of the machine 115 and/or applying the braking action to bring the machine 115 to a halt in order to mitigate collision with a detected obstruction in front of the machine 115, the steering latency, or any other factor associated with a linear or longitudinal movement of the machine 115. For example, the zone creation module 460 is also configured to dynamically increase or decrease the longitudinal extension A of the at least one virtual safety zone 700 based on the current speed of the machine 115 and/or a distance of the machine 115 from an object or an obstruction detected in front of the machine 115 by the remote sensing system 120. It should be understood that an increase in the monitored current speed of the machine 115 results in an increase in the stopping distance, for example, 715-2 of the machine 115, and the dynamic increase in the longitudinal extension A of the at least one virtual safety zone 700 is indicative of the increase in the stopping distance, for example, 715-2 of the machine 115.

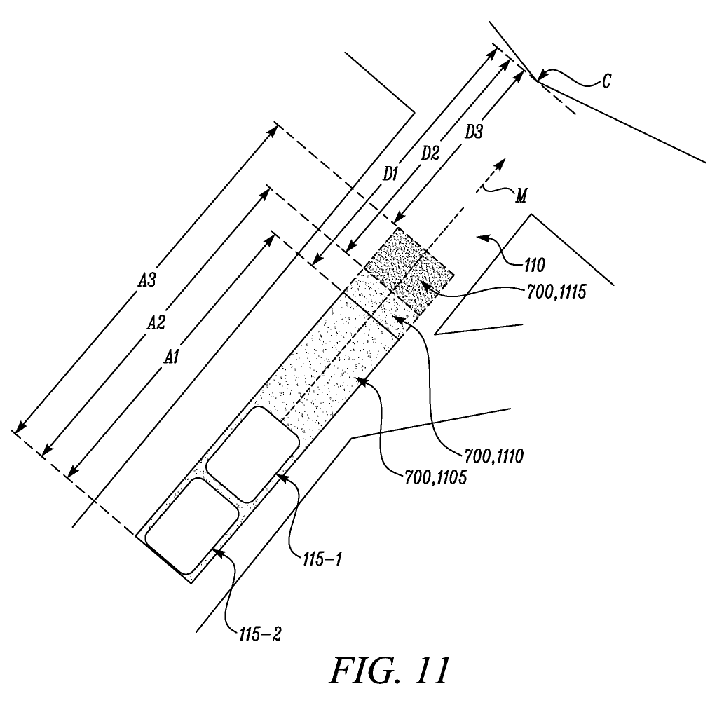

Referring to FIG. 11, an illustration of exemplary dynamic variations in the longitudinal extension A (see FIG. 7) of at least one virtual safety zone, for example, (700, 1105), (700, 1110), (700, 1115) created by the zone creation module 460 is shown. The zone creation module 460 is configured to create the virtual safety zone 700, 1105 when the machine 115 is traversing the passageway 110 at a first speed and/or is at a first distance D1 from an object, for example, a corner C in the passageway 110. Similarly, the zone creation module 460 is configured to create the virtual safety zone 700, 1110 when the machine 115 is traversing the passageway 110 at a second speed and/or is at a second distance D2 from the corner C in the passageway 110. Similarly, the zone creation module 460 is configured to create the virtual safety zone 700, 1115 when the machine 115 is traversing the passageway 110 at a third speed and/or is at a third distance D3 from the corner C in the passageway 110. In embodiments, the second speed is greater than the first speed and the third speed is greater than the second speed. In embodiments, the second distance D2 is less than the first distance D1 and the third distance D3 is less than the second distance D2.

In embodiments, the zone creation module 460 is also configured to dynamically vary the lateral extension B of the at least one virtual safety zone, for example, 700 based on one or more lateral extension factors including, but not limited to, the determined actual clearance, for example, C1, C2 (see FIGS. 5 and 6), the estimated clearance, for example, C3, C4, C5, C6 (see FIGS. 5 and 6) of the machine 115 with the side walls, for example, S1 and/or S2, the monitored current machine speed, the monitored steering rate, the monitored current steering angle, an angular velocity, the current articulation angle ϴ (see FIG. 8) defined between the first machine section 115-1 and the rear machine section 115-2, the steering latency, or any other factor associated with a lateral movement of the machine 115. For example, the zone creation module 460 is configured to dynamically increase the lateral extension of the at least one virtual safety zone 700 along at least one lateral side, for example, L1, L2 of the machine 115 when the determined actual clearance, for example, C1, C2, and/or the estimated clearance, for example, C3, C4, C5, C6 decreases along the direction of movement M of the machine 115 in the passageway 110. Similarly, the zone creation module 460 is configured to dynamically decrease the lateral extension B of the at least one virtual safety zone 700 along the at least one lateral side, for example, L1, L2 of the machine 115 when the determined actual clearance, for example, C1, C2, and/or the estimated clearance, for example, C3, C4, C5, C6 continuously increases or is constant for a predefined time duration along the direction of movement of the machine 115 in the passageway 110. In embodiments, the zone creation module 460 is configured to equally distribute the lateral extension B along both the lateral sides L1, L2 of the machine 115 when the determined actual and/or estimated clearance, for example, C1, C2, C3, C4, C5, C6 between the lateral sides L1, L2 and the side walls S1, S2 are equal or constant for the predefined time duration respectively. In embodiments, the zone creation module 460 is configured to symmetrically distribute the lateral extension B of the created virtual zone(s) 700 around the longitudinal axis LA (see FIGS. 5 and 7) of, for example, both the first and rear machine sections 115-1, 115-2, of the machine 115. In embodiments, the lateral extension of the at least one virtual safety zone encompasses the machine 115.

In embodiments, the zone creation module 460 is also configured to predict a change in the determined actual and/or estimated clearance, for example, C1, C2, C3, C4, C5, C6, and/or a rate of change of the determined actual and/or estimated clearance, between at least one lateral side, for example, L1, L2 of the machine 115 and the at least one side wall, for example, S1, S2 based on the monitored environment, the monitored steering angle and/or rate, the generated 3D view, and/or the detected proximity of the at least one side wall by the remote sensing system 120 (see FIG. 1) in front of and along the direction of movement M of the machine 115. In embodiments, the zone creation module 460 is configured to dynamically increase the lateral extension B of the at least one virtual safety zone 700 along the at least one lateral side, for example, L1, L2 of the machine 115 when the predicted change or the predicted rate of change is indicative of a decrease in the determined actual and/or estimated clearance, for example, C1, C2, C3, C4, C5, C6 between the at least one lateral side, for example, L1 of the machine 115 and the at least one side wall, for example, S1 adjacent of the at least one lateral side, for example, L1 of the machine 115. Similarly, the zone creation module 460 is configured to dynamically decrease the lateral extension B of the at least one virtual safety zone 700 along the at least one lateral side, for example, L1, L2 of the machine 115 when the predicted change or the predicted rate of change is indicative of an increase in the determined actual and/or estimated clearance, for example, C1, C2, C3, C4, C5, C6 between the at least one lateral side, for example, L1 of the machine 115 and the at least one side wall, for example, S1 adjacent of the at least one lateral side, for example, L1 of the machine 115. Further, the zone creation module 460 is configured to equally distribute the lateral extension B along both the lateral sides, L1, L2 of the machine 115 when the predicted change or the predicted rate of change is nil, proximate, or equal to the determined actual and/or estimated clearance, for example, C1, C2, C3, C4, C5, C6, between the lateral sides L1, L2 of the machine 115 and adjacent side walls S1, S2 of the passageway 110 respectively.

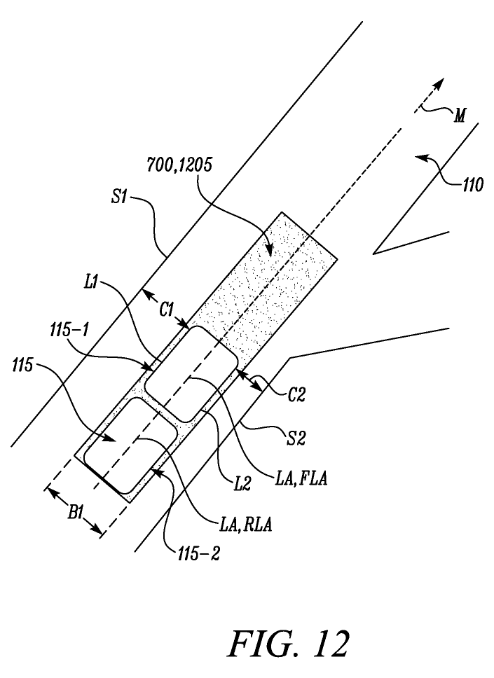

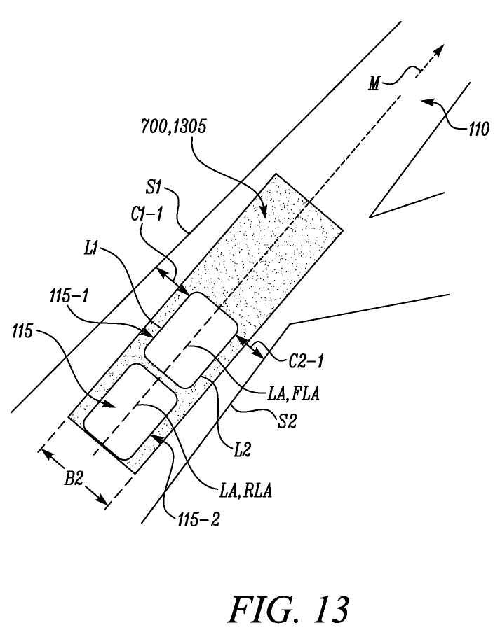

Referring to FIGS. 12 and 13, an exemplary illustration of the lateral extension, for example, B1, B2 of the at least one created virtual safety zone 700 (see FIG. 7), for example, 700, 1205 and 700, 1305 created by the zone creation module 460 (also see FIG. 7) is shown. In embodiments, the zone creation module 460 is configured to laterally extend the at least one created virtual safety zone 700, for example, 700, 1205, from each lateral side, for example, L1, L2 dynamically based on the determined actual clearance, for example, C1, C2 and/or the estimated clearance, for example, C3, C4, C5, C6 (see FIGS. 5 and 6). For example, the zone creation module 460 is configured to laterally extend the at least one created virtual safety zone 700, for example, 700, 1205 equally on both the lateral sides, for example, L1, L2 of the machine 115 for the predefined distance B1 to define the modified virtual safety zone, for example, 700, 1305 when the determined actual clearance, for example, C1, C2 of the lateral sides L1, L2 of the machine 115 with the side walls S1 and S2 of the passageway 110 at a first time instant is the same (i.e. C1 = C2) or constant for the predefined time duration (i.e. C1 and C2 remain same during the predefined time duration) respectively. In embodiments, the zone creation module 460 is configured to dynamically increase the lateral extension of the at least one created virtual safety zone 700 equally on both the lateral sides, for example, L1, L2 of the machine 115 for the predefined distance B2 when the determined actual clearance, for example, C1-1, C2-1 of the lateral sides L1, L2 of the machine 115 with the side walls S1 and S2 of the passageway 110 at a second time instant is the same (i.e. C1-1 = C2-1) or constant respectively and continuously decreases along the direction of movement of the machine 115 and/or is less than the determined actual clearance, for example, C1, C2 of the lateral sides L1, L2 of the machine 115 at the first instant, i.e., C1-1 is less than C1 determined at the first time instant and/or C2-1 is less than C2 determined in the first time instant.

In embodiments, the zone creation module 460 is also configured to dynamically vary the lateral extension B (see FIG. 7) of the at least one created virtual safety zone 700 (see FIG. 7) along only one lateral side, for example, a first lateral side L1 of the lateral sides L1, L2 of the machine 115 based on the proximity, the determined actual clearance, for example, C1 (see FIGS. 5 and 6) and/or estimated clearance, for example, C3, C4, C5, C6 (see FIGS. 5 and 6) of the first lateral side L1 with a first side wall, for example, S1 (see FIGS. 5 and 6) of the side walls S1, S2 (see FIGS. 5 and 6) of the passageway 110. For example, the zone creation module 460 is configured to increase the lateral extension B of the at least one created virtual safety zone 700 along the first lateral side L1 of the machine 115 when the determined actual clearance, for example, C1 continuously decreases along the direction of movement M of the machine 115 and/or when the estimated clearance, for example, C3 of first lateral side L1 of the machine 115 with the first side wall S1 is less than the determined actual clearance, for example, C1 of first lateral side L1 with the first side wall S1. In embodiments, the zone creation module 460 (also see FIG. 7) is configured to increase the lateral extension B of the at least one created virtual safety zone 700 along the first lateral side L1 of the machine 115 based on the monitored steering rate and/or angle of the machine 115. In embodiments, the increase in the lateral extension B of the at least one created virtual safety zone 700 along the first lateral side L1 of the machine 115 is indicative of a preventive action to be taken or considered to mitigate machine collision of the first lateral side L1 of the machine 115 with the side wall, for example, S1 of the passageway 110.

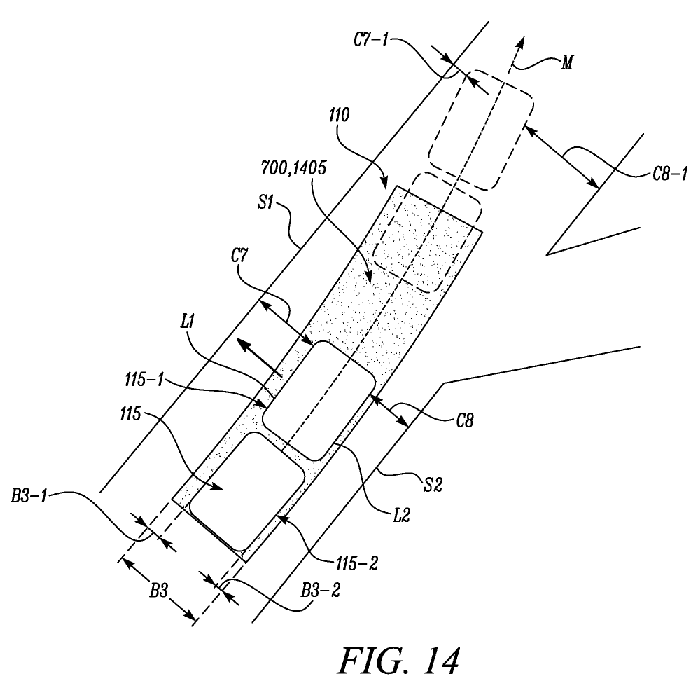

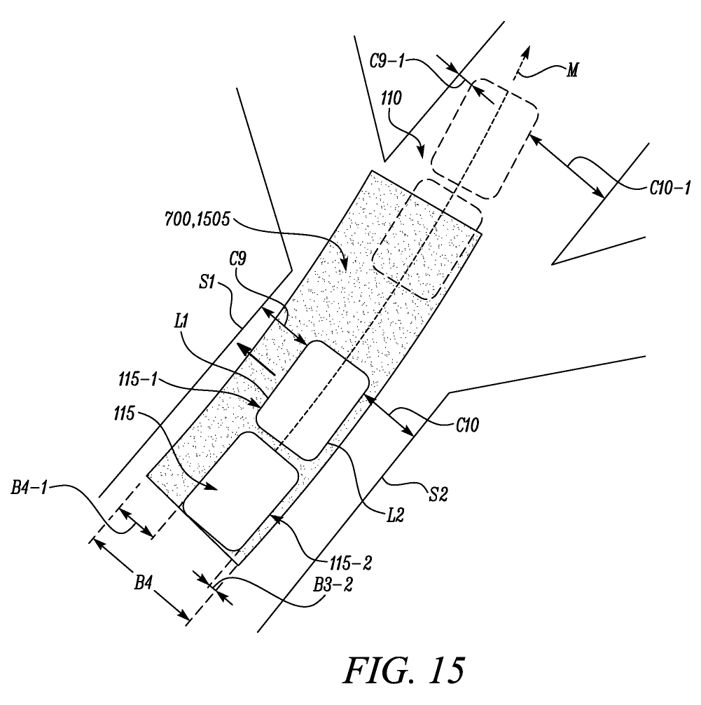

For example, referring to FIGS. 14 and 15, the lateral extension, for example, B3, B4 of the at least one created virtual safety zone 700 (see FIG. 7), for example, 700, 1405, and 700, 1505 by the zone creation module 460 (also see FIG. 7) along the first lateral side L1 of the machine 115 is shown. In embodiments, the zone creation module 460 is configured to increase the lateral extension B1 (see FIG. 12) of the at least one created virtual safety zone 700, for example, 700, 1205 (see FIG. 12) to B3 to define the modified virtual safety zone, for example, 700, 1405, when the determined actual clearance C1 (see FIG. 6) of the first lateral side L1 with the first side wall S1 decreases to C7 along the direction of movement M of the machine 115, for example, based on the monitored steering angle and/or rate of the machine 115 and/or when a proximity of the first lateral side L1 with the first side wall S1 increases. In particular, the zone creation module 460 is configured to increase the lateral extension B1 by a lateral extension B3-1 along the lateral side L1 of the machine 115 based on the determined decrease in the determined actual clearance from C1 to C7. In embodiments, the zone creation module 460 is also configured to decrease and/or maintain the lateral extension, for example, B3-2 along the other lateral side L2 of the machine 115 to a predefined distance from the lateral side L2 based on the determined increase in the determined actual clearance from C2 (see FIG. 6) to C8. Similarly, the zone creation module 460 is configured to dynamically increase the lateral extension B3 of the at least one created virtual safety zone 700, for example, 700, 1405 to B4 to define the modified virtual safety zone, for example, 700, 1505, when the determined actual clearance C7 of the first lateral side L1 with the first side wall S1 decreases to C9 along the direction of movement M of the machine 115, for example, based on the monitored steering angle ϴ and/or rate of the machine 115 and/or when the proximity of the first lateral side L1 with the first side wall S1 increases further than a previously determined proximity of the first lateral side L1 with the first side wall S1. In particular, the zone creation module 460 is configured to increase the lateral extension from B3-1 to B4-1 along the first lateral side L1 of the machine 115 based on the determined decrease in the determined actual clearance from C7 to C9. In embodiments, the zone creation module 460 is also configured to decrease and/or maintain the lateral extension, for example, B3-2 along the other lateral side L2 of the machine 115 to the predefined distance from the lateral side L2 based on the increase in the actual clearance determined by the zone creation module 460 from C8 to C10. Similarly, the zone creation module 460 is also configured to increase and/or decrease the lateral extension, for example, B1 of the at least one created virtual safety zone 700 along the first lateral side L1 based on the estimated clearance, for example, C3, C4, C5, C6 (see FIGS. 5 and 6), the predicted change in the determined actual and/or estimated clearance, for example, from C7 to C7-1 or from C3 to C7-1, and/or the predicted rate of change of the determined actual and/or estimated clearance between the first lateral side L1 and the side wall S1 of the passageway 110.

Referring again to FIG. 3, the action module 465 is configured to detect an obstacle and/or an incursion in the at least one virtual safety zone 700 (e.g. in zones 705, 710, 715, and/or 720 (see FIG. 7) based on the monitored environment and/or the generated 3D view by the remote sensing system 120 (see FIG. 1), and/or the determined actual and/or estimated clearance, for example, C1, C2, C3, C4, C5, C6 (see FIGS. 5 and 6) by the determination module 455. In embodiments, the action module 465 is configured to detect the obstacle and/or incursion along the longitudinal extension A (see FIG. 7) and in the direction of movement M of the machine 115, for example, when another object or machine enters the at least one virtual safety zone 700 from an opposite direction to the direction of movement M of the machine 115. Similarly, the action module 465 is configured to detect the obstacle and/or incursion along the lateral extension B, B1, B2, B3, B4 (see FIGS. 7 and 12-15) in the direction perpendicular to the direction of movement M of the machine 115, for example, when another object or machine enters the at least one virtual safety zone 700 from a lateral direction and/or passageway perpendicular to the direction of movement M of the machine 115. In embodiments, the action module 465 is configured to perform at least one action based on the detection and/or when the determined actual and/or estimated clearance, for example, C1, C2, C3, C4, C5, C6 is less than at least one threshold clearance.

In accordance with various embodiments, the action module 465 is configured to perform the at least one action of providing, via the output device 135 (see FIG. 1) and/or the display device 315 (see FIG. 3), an alert or warning prior to the machine 115 approaching the obstacle and/or the at least one lateral side, for example, L1, L2 of the machine 115 approaching the at least one threshold clearance with the at least one side wall, for example, S1, S2 of the passageway 110. In embodiments, the action module 465 is also configured to perform the at least one action of minimizing the monitored current speed of the machine 115, limiting the monitored current speed of the machine 115 to a threshold speed, modifying the monitored steering rate or steering angle of the machine 115, and/or initiating the braking action to halt the machine 115 when the remote sensing system 120 detects the obstacle and/or incursion in the at least one virtual safety zone 700.

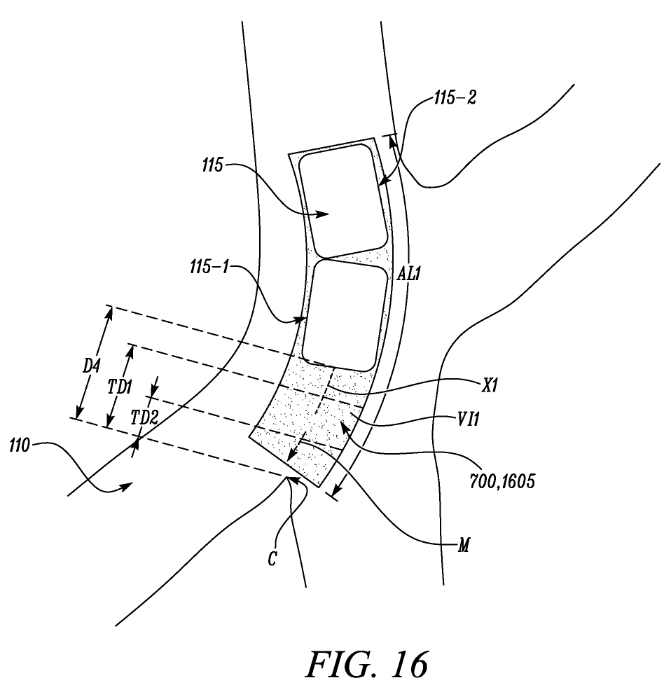

As an example, the action module 465 is configured to provide the alert and/or warning, via the output device 135 such as an alarm system (not shown) and/or the display device 315 (see FIG. 3) when the determined actual and/or estimated distance, for example, D1, D2, D3 (see FIG. 11) is less than at least one threshold distance, for example, TD1, TD2 (see FIG. 16) and/or when the action module 465 detects the incursion in front of and along the direction of movement M of the machine 115 in the at least one created virtual safety zone 700 (see FIG. 7). As another example, the action module 465 is configured to minimize the monitored current speed of the machine 115 and/or limit the monitored current speed of the machine 115 to the threshold speed upon the detection of the obstacle and/or incursion in the fourth virtual safety zone 720 (see FIG. 7). In yet another example, the action module 465 is configured to initiate the braking action to halt the machine 115 upon the detection of the obstacle and/or incursion in the third virtual safety zone 715 (see FIG. 7) and/or at the determined stopping distance 715-2 (see FIG. 7) and/or a start of the third safety zone 715 at 715- 1 (see FIG. 7) such that the machine 115 stops at least at the determined stopping distance 715-2 after the initiation of the braking action by the machine 115.

In accordance with various embodiments, the action module 465 is also configured to provide, via the output device 135 (see FIG. 1) and/or the display device 315 (see FIG. 3), the alert or warning as one or more visual indications when the determined actual and/or estimated distance, for example, D1, D2, D3 (see FIG. 11) is less than or equal to the at least one threshold distance, for example, TD1, TD2 (see FIG. 16). Examples of the visual indication(s) include, but are not limited to, colors, patterns, icons, animations, and/or images.

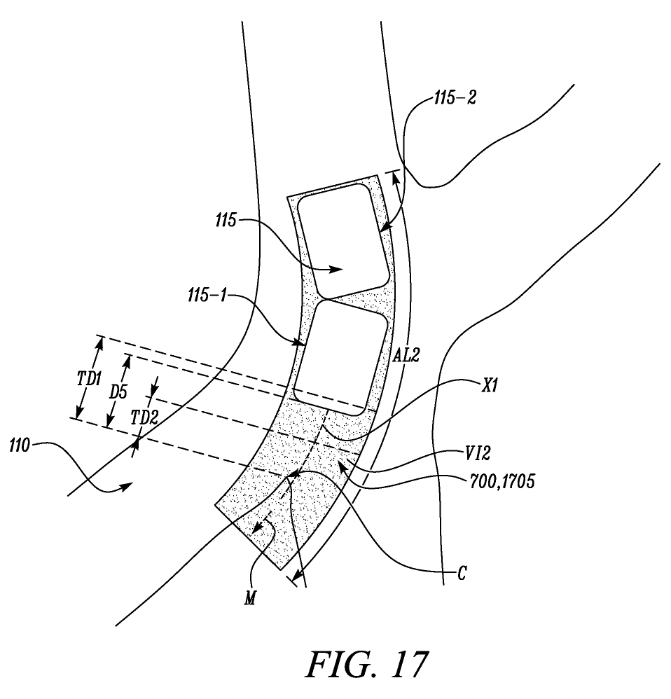

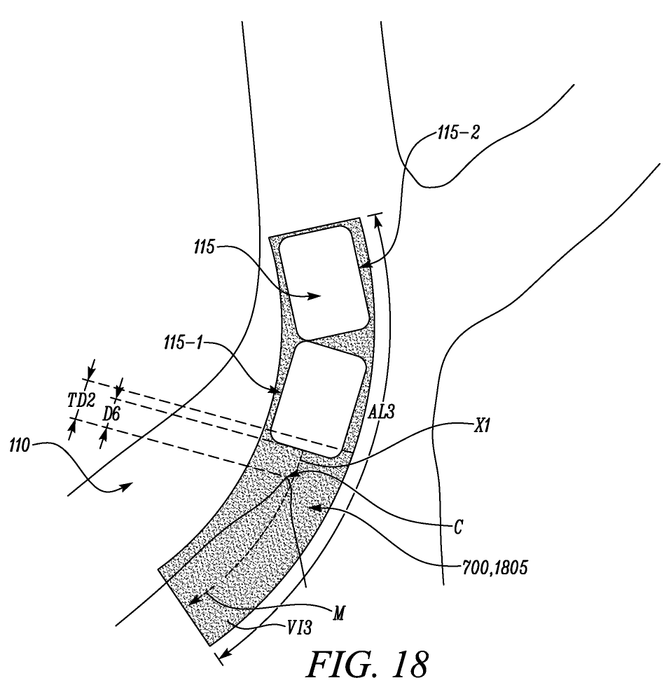

For example, referring to FIGS. 16-18, illustrations of exemplary visual indications provided by the action module 465 to indicate the alert or warning are shown. In embodiments, the zone creation module 460 is configured to warp or curve the rectangular shape of the at least one created virtual safety zone 700 (see FIG. 7) to the virtual safety zone 700, 1605 having an arc length, for example, AL1 based on the articulation angle ϴ (see FIG. 8) of the machine 115. In embodiments, the action module 465 is configured to provide a first visual indication VI1 in a first color corresponding to the virtual safety zone 700, 1605 when the monitored current speed of the machine 115 is within a threshold speed, when the distance D4 of the machine 115 from the object/obstruction, for example, the corner C, detected in the passageway 110 by the remote sensing system is greater than a first threshold distance TD1, and/or when the corner C is beyond the fourth safety zone 720 (see FIG. 7). The zone creation module 460 is also configured to dynamically increase the longitudinal extension A (see FIG. 7) of the virtual safety zone 700, 1605 to define the virtual safety zone 700, 1705 having the arc length AL2 greater than the arc length AL1 along the projected path X1 of the machine 115 based on the longitudinal extension factor(s), for example, when the monitored current speed is greater than the threshold speed and/or the distance D5 of the machine 115 from the object/obstruction, for example, the corner C in the passageway 110 is less than the first threshold distance TD1. It may be understood that the longitudinal extension A of the at least one virtual safety zone 700 (see FIG. 7) corresponds to an extension of arc length, for example, AL1 (i.e.inner and/or outer arch lengths of the curved rectangular shape of the at least one virtual safety zone, for example, 700, 1705) of the warped or curved virtual safety zone 700, 1605. The action module 465 is then configured to provide a second visual indication VI2 in a second color corresponding to the virtual safety zone 700, 1705 when the monitored current speed is greater than the threshold speed, the distance D5 of the machine 115 from the object/obstruction, for example, the corner C in the passageway 110 is less than the first threshold distance TD1, and/or the corner C is within the fourth virtual safety zone 720. The zone creation module 460 is also configured to dynamically further increase the longitudinal extension A (see FIG. 7) of the virtual safety zone 700, 1705 to define the virtual safety zone 700, 1805 having the arc length AL3 greater than the arc length AL2 along the projected path X1 of the machine 115, for example, when the monitored current speed is greater than the threshold speed and/or the distance D6 of the machine 115 from the object/obstruction, for example, the corner C in the passageway 110 is less than a second threshold distance TD2. The action module 465 is then configured to provide a third visual indication VI3 in a third color corresponding to the virtual safety zone 700 when the monitored current speed is greater than the threshold speed, the distance D6 of the machine 115 from the object/obstruction, for example, the corner C in the passageway 110 is less than a second threshold distance TD2, and/or the corner C is within the third virtual safety zone 715 (see FIG. 7). In embodiments, the action module 465 is also configured to automatically minimize the current speed of the machine 115 when the monitored current speed is greater than the threshold speed, the distance D5 of the machine 115 from the object/obstruction, for example, the corner C in the passageway 110 is less than the first threshold distance TD1, and/or the corner C is within the fourth virtual safety zone 720 (see FIG. 7). In embodiments, the action module 465 is also configured to automatically initiate the braking action to halt the machine 115 when the distance D6 of the machine 115 from the object/obstruction, for example, the corner C in the passageway 110 is less than the second threshold distance TD2 and/or the corner C is within the third virtual safety zone 715 (see FIG. 7) to mitigate collision of the machine 115 with the object/obstruction, for example, the corner C in the passageway 110.

As another example, the action module 465 is configured to provide the alert and/or warning, via the output device 135 such as an alarm system (not shown) and/or the display device 315 (see FIG. 3) when the determined actual and/or estimated clearance, for example, C1, C2, C3, C4, C5, C6 (see FIGS. 5 and 6) is less than the at least one threshold clearance and/or when the action module 465 detects the incursion of the at least one side wall, for example, S1 in the at least one created virtual safety zone. As another example, the action module 465 is also configured to automatically modify the monitored steering rate or steering angle of the machine 115 when the determined actual and/or estimated clearance, for example, C1, C2, C3, C4, C5, C6 (see FIGS. 5 and 6) is less than the at least one threshold clearance and/or when the action module 465 detects the incursion of the at least one side wall, for example, S1 in the at least one created virtual safety zone. In yet another example, the action module 465 is configured to minimize the monitored current speed of the machine 115 and/or limit the monitored current speed of the machine 115 to the threshold speed upon the detection of the obstacle and/or incursion in the fourth virtual safety zone 720 (see FIG. 7). In yet another example, the action module 465 is configured to initiate the braking action to halt the machine 115 upon the detection of the obstacle and/or incursion in the third safety zone 715 (see FIG. 7) and/or at the determined stopping distance 715-2 (see FIG. 7) and/or a start of the third virtual safety zone 715 at 715-1 (see FIG. 7) such that the machine 115 stops at least at the determined stopping distance 715-2 after the initiation of the braking action by the machine 115.

In accordance with various embodiments, the action module 465 is also configured to provide, via the output device 135 (see FIG. 1) and/or the display device 315 (see FIG. 3), the alert or warning as one or more visual indications when the determined actual and/or estimated clearance, for example, C1, C2, C3, C4, C5, C6 (see FIGS. 5 and 6) is less than or equal to the at least one threshold clearance.

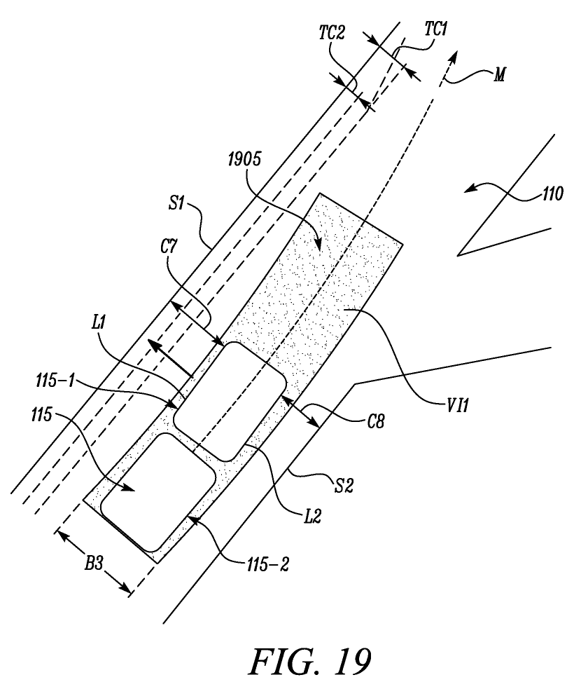

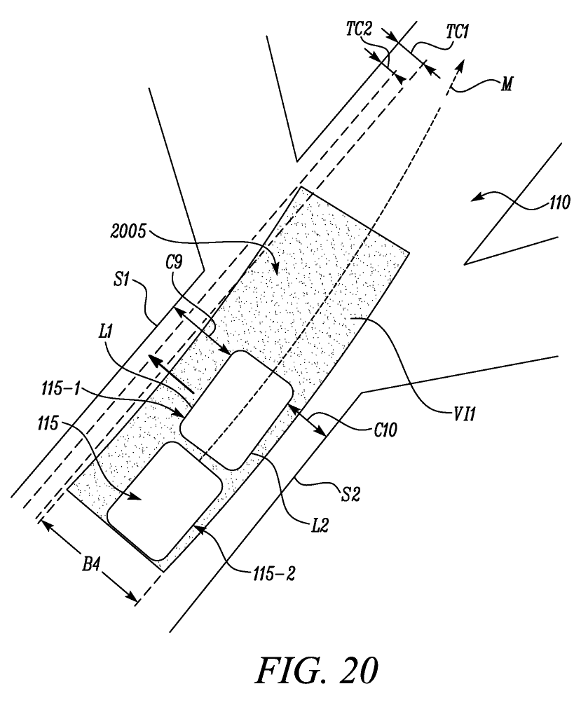

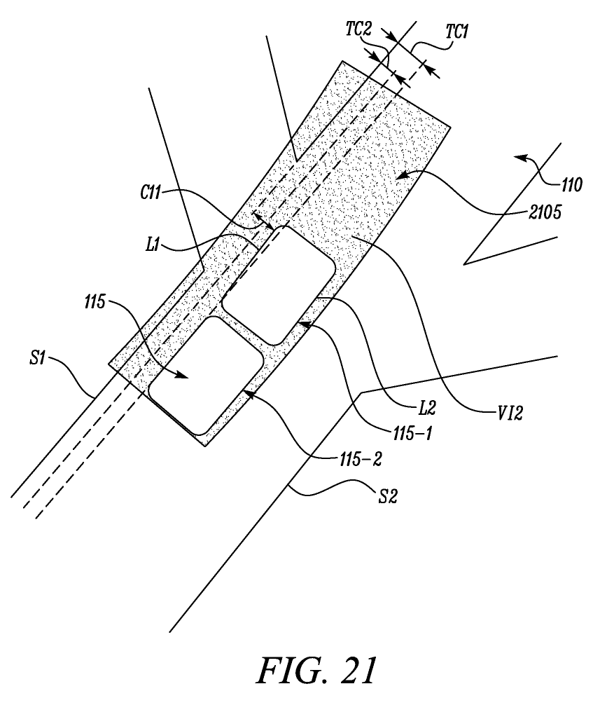

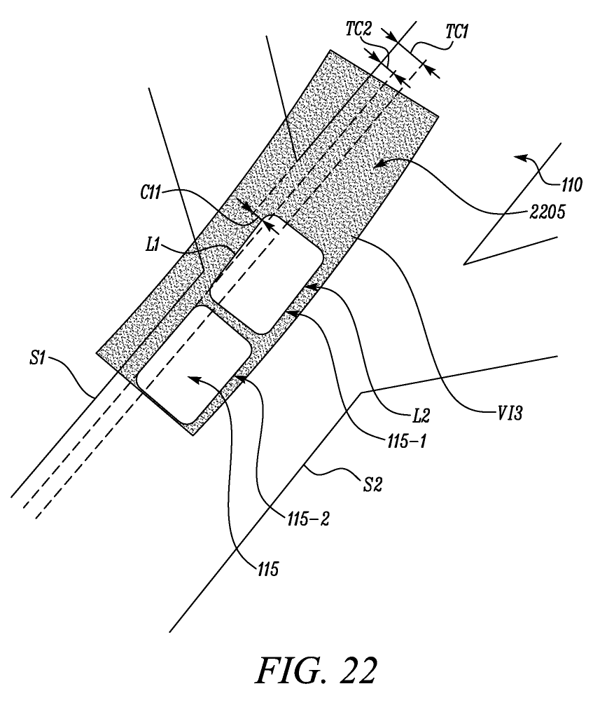

For example, referring to FIGS. 19-22, the action module 465 providing the alert or warning as one or more visual indications is shown. In embodiments, the action module 465 is configured to increase the lateral extension B3 of the at least one created virtual safety zone 700, for example, the virtual safety zone 700, 1905 to B4 to define the virtual safety zone 700, 2005, along the first lateral side L1 of the machine 115 based on the monitored steering angle and/or rate by the remote sensing system 120 (see FIG. 1), the determined actual and/or estimated clearance, for example, C1, C1-1, C2, C2-1 at different time instants, and/or corresponding to the movement of the machine 115 towards the first side wall S1 and away from the other side wall S2. In embodiments, the action module 465 is configured to provide the first visual indication VI1 in a first color corresponding to the at least one created virtual safety zone 700 when action module 465 detects no intrusion and/or obstacle in the at least one created virtual safety zone 700, for example, the virtual safety zone 700, 1905. Similarly, the action module 465 is configured to provide the second visual indication VI2 in a second color corresponding to the at least one created virtual safety zone 700 when the action module 465 detects the intrusion of the first side wall S1 in the at least one created virtual safety zone 700, for example, the virtual safety zone 700, 2005, and/or the virtual safety zone 700, 2105 and/or when the determined actual and/or estimated clearance, for example, C11 is less than or equal to a first threshold clearance TC1 corresponding to a continued movement of the machine 115 towards the first side wall S1. Further, the action module 465 is configured to provide the third visual indication VI3 in a third color corresponding to the at least one created virtual safety zone 700, for example, the virtual safety zone 700, 2205 when action module 465 detects the intrusion of the first side wall S1 in the at least one created virtual safety zone 700, and/or when the determined actual and/or estimated clearance, for example, C12 is less than or equal to a second threshold clearance TC2, that is less than first threshold clearance TC1, corresponding to a continued movement of the machine 115 towards the first side wall S1. In embodiments, the action module 465 is also configured to automatically minimize the current speed of the machine 115 when the action module 465 detects the intrusion of the first side wall S1 in the at least one created virtual safety zone 700, and/or the determined actual and/or estimated clearance, for example, C11 is less than or equal to the first threshold clearance TC1. In embodiments, the action module 465 is also configured to automatically initiate the braking action to halt the machine 115 when the determined actual and/or estimated clearance, for example, C11 is less than or equal to the second threshold clearance TC2 to mitigate collision of the machine 115 and/or the first lateral side L1 of the machine 115 with the first side wall S1 of the passageway 110.

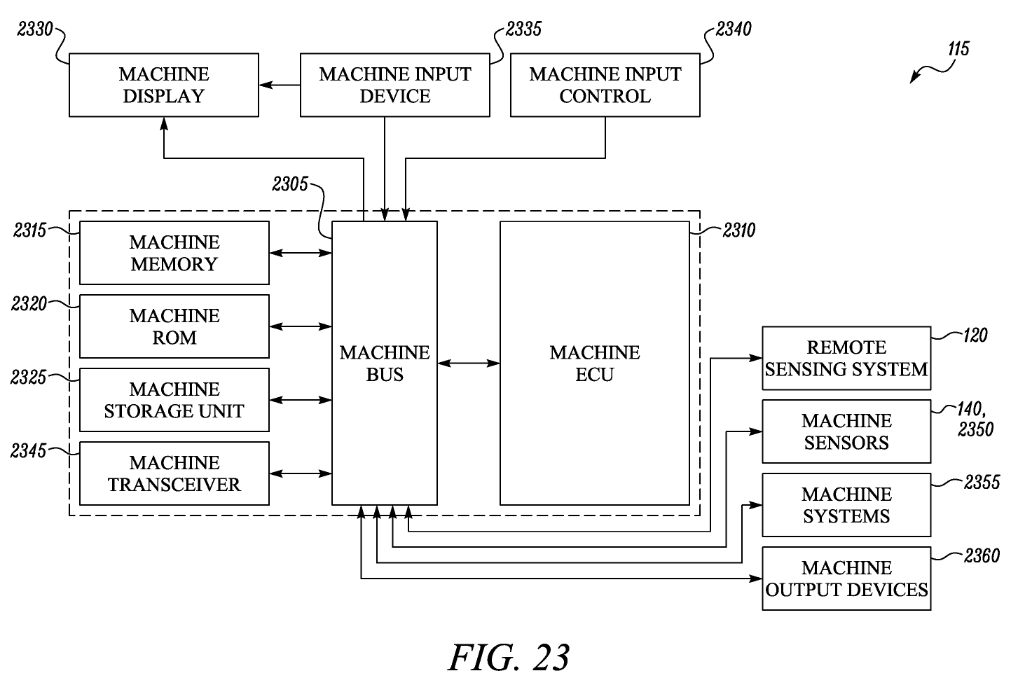

The various components of the machine 115 will now be described hereinafter with respect to FIG. 23. It should be appreciated by those of ordinary skill in the art that FIG. 23 depicts the machine 115 in a simplified manner and a practical embodiment includes additional components and suitably configured functions and/or logic to support known or conventional operating features that are not described in detail herein.

Referring now to FIG. 23, the exemplary machine 115 includes a machine system 2300 having machine components 2305-2345, for example, similar to the system components 405-445 (see FIG. 4) of the exemplary controller 125 of FIG. 4 respectively. For example, the machine 115 includes the machine system 2300 having a machine bus 2305, a machine processor 2310, herein referred to as ‘machine electronic control unit (ECU) 2310’ or ‘machine ECU 2310’, a machine memory 2315, a machine ROM 2320, a machine storage unit 2325, a machine display 2330, a machine input device(s) 2335, a machine input control 2340, and a machine transceiver 2345. In embodiments, the machine components 2305-2345 may also be configured to perform one or more similar functions as the system components 405-445 of the controller 125. In embodiments, the machine 115 also includes the remote sensing system 120 (see FIG. 1). Although the machine system 2300 is illustrated and described to be implemented within a single device and/or the machine 115, it is contemplated that the one or more components of the machine system 2300 are alternatively implemented in a distributed computing environment and/or retrofitted to the machine 115. In embodiments, the machine 115 also includes the monitoring device(s) 140 (see FIG. 1), for example, but not limited to, one or more machine sensors 2350 for monitoring one or more parameters of the machine 115 and determining machine- related information. Examples of the machine sensor(s) include, but are not limited to, one or more fuel sensors, fluid sensors, speed sensors, position sensors, proximity sensors, optical sensors, magnetic sensors, image sensors, and radar sensors. Examples of the one or more parameters and/or the machine-related information include, but are not limited to, a current speed, a steering angle and/or rate, and a current position of the machine 115. Further, the machine 115 includes one or more additional devices and/or components including, but not limited to, one or more machine systems 2355, and/or one or more machine output devices 2360 coupled with the machine ECU 2310. Examples of the additional machine system(s) 2355 include, but are not limited to, mechanical and electronic/electrical systems. Examples of the additional mechanical system(s) include, but are not limited to, engine, transmission, braking, thermal, and steering systems. Examples of electronic/electrical system(s) include, but are not limited to, ignition and alternator, anti-lock braking system (ABS), airbag systems, and advanced driver-assistance systems (ADAS), global positioning system (GPS), and global navigation satellite system (GNSS). Examples of the one or more machine output devices 2360 include, but not limited to, alert/alarm systems, speakers, and visual indicators. Further, although a single machine ECU 2310 is illustrated, it will understood by those with ordinary skill in the art that the machine ECU 2310 is configurable to include multiple machine controllers or ECUs in communication with each other and configured to control different functions or operations of the machine 115 including, but not limited to, ECMs for controlling machine engine or ground speed, machine implement operation, machine alarm systems, and machine activation and/or shut-down operation.

In embodiments, for instances when the machine 115 is remotely controlled and/or operated via the network 130 by the controller 125 (see FIGS. 1 and 4) provided in a remote location such as the remote operator station (ROS) 300 (see FIG. 3) from the machine 115, the machine ECU 2310 is configured to receive one or more control signals from the controller 125 via the network 130. In such embodiments, the machine ECU 2310 is configured to initiate one or more controls, actions, and/or functions including, but not limited to, initiating a movement, a braking action, a halting, and/or an alert/alarm system, of the machine 115 based on the control signal(s) received from the controller 125 via the network 130. In such embodiments, the controller 125 is configured to control one or more parameters including, but not limited to, the current speed, and/or the steering rate or angle of the machine 115 via the machine ECU 2310 and the network 130. In such embodiments, the machine ECU 2310 is also configured to monitor one or more machine operations via the machine sensors 2350 and/or the remote sensing system 120 provided in the machine 115. In such embodiments, the machine ECU 2310 is configured to receive one or more monitored inputs from the machine sensors 2350. Examples of the one or more monitored inputs include, but are not limited to, a proximity of the machine 115 and/or the lateral side(s), for example, L1, L2 (see FIG. 1) of the machine 115 to the side wall(s), for example, S1, S2 (see FIG. 1) of the passageway 110, a 3-dimensional (3D) view of the environment E of the passageway 110 in front of and along the direction of movement M (see FIG. 1) of the machine 115, a current location of the machine 115, a current steering angle and/or current steering rate of the machine 115, a current angle of one or more wheels of the machine 115 with reference to a longitudinal axis (not shown) of the machine 115, and a current acceleration and/or velocity of the machine 115. In such embodiments, the machine ECU 2310 is also configured to provide the received monitored input(s) to the controller 125 via the network 130. In such embodiments, the machine ECU 2310 is also configured to receive one or more control signals indicative of the movement of the machine 115 to be initiated in the forward or rearward and/or lateral direction, an amount of acceleration/deceleration and/or a steering angle or steering rate of the machine 115 to be implemented from the controller 125 via the network 130. In embodiments, the machine ECU 2310 is configured to initiate the movement of the machine 115 in the forward or rearward and/or lateral direction based on the amount of acceleration/deceleration and/or the steering angle or the steering rate of the machine 115 defined in the control signal(s). For example, the machine ECU 2310 is configured to operate one or more machine systems including, but not limited to, the transmission system and the steering system to initiate the movement of the machine 115 based on the control signal(s) received from the controller 125 via the network 130.

In embodiments, for instances when the machine 115 is manually and/or autonomously operated, the machine ECU 2310 is configured to perform the functions of the exemplary controller 125 of FIG. 4 and/or the one or more modules, for example, 450, 455, 460, 465 (see FIG. 4) of the controller 125 independently. For example, the machine ECU 2310 is configured to receive at least one input from the remote sensing system 120. In such embodiments, the machine ECU 2310 is also configured to monitor a current speed of the machine 115 and a steering angle or a steering rate of the machine 115 defined by the machine input device 2335 in communication with the machine ECU 2310 during the movement of the machine 115. In such embodiments, the machine ECU 2310 is also configured to determine the estimated distance (e.g. the stopping distance 715-2 (see FIG. 7) the machine 115 is expected to travel after a braking action is performed to bring the machine 115 to a halt based on the monitored current speed. In such embodiments, the machine ECU 2310 is also configured to determine an actual or estimated distance, for example, D1 through D6 (see FIGS. 11 and 16-18) of the machine 115 from the object/obstruction, for example, the corner C (see FIGS. 11 and 16-18) detected based on the received input from the remote sensing system 120. In such embodiments, the machine ECU 2310 is also configured to determine an actual and/or an estimated clearance, for example, C1, C2, C3, C4, C5, C6 (see FIGS. 5 and 6) between the at least one lateral side, for example, L1, L2 of the machine 115 with the at least one side wall, for example, S1, S2 of the passageway 110 based on the received input from the remote sensing system 120, and/or the monitored steering angle or steering rate of the machine 115. In such embodiments, the machine ECU 2310 is also configured to create the at least one virtual safety zone, for example, 700 (see FIG. 7) that dynamically extends longitudinally along the direction of movement M of the machine 115 and laterally from each lateral side, for example, L1, L2 of the machine 115 in real-time based on the one or more longitudinal and/or lateral extension factors, for example, the monitored environment E by the remote sensing system 120, the monitored current speed, the estimated or stopping distance, for example, 715-2 (see FIG. 7) and the determined actual and/or estimated clearance, for example, C1, C2, C3, C4, C5, C6 (see FIGS. 5 and 6). In such embodiments, the machine ECU 2310 is also configured to perform at least one action including, but not limited to, minimizing the current speed and/or initiating the braking action of the machine 115, upon detection of the incursion or obstacle in the at least one virtual safety zone, for example, 700 and/or when the estimated clearance, for example, C1, C2, C3, C4, C5, C6 is less than at least one threshold clearance, for example, TC1, TC2 (see FIGS. 14 and 15).

### Industrial Applicability

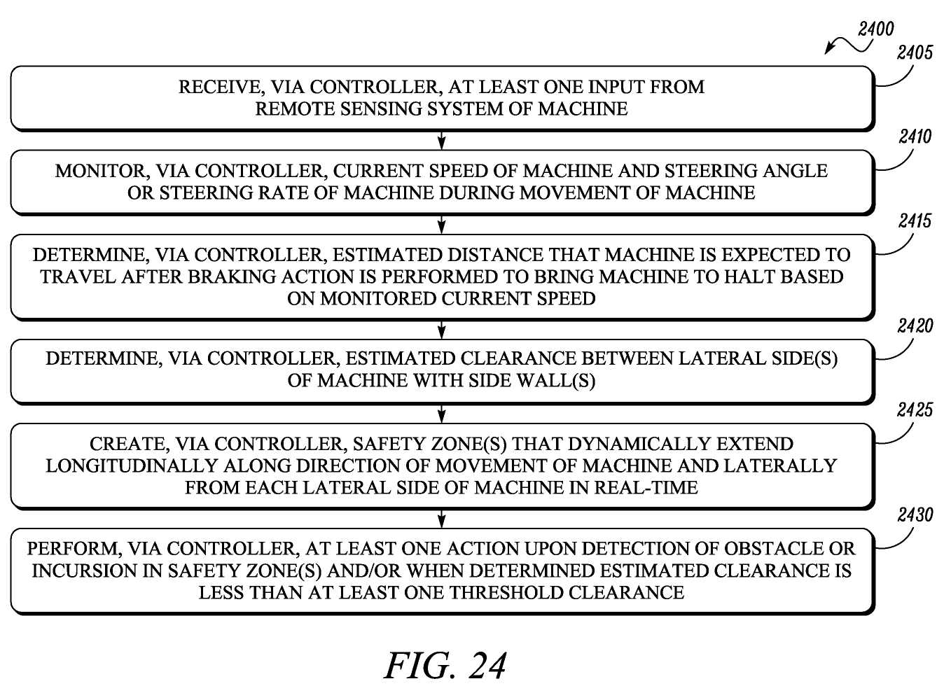

Referring to FIG. 24, a method 2400 for mitigating machine collision in the exemplary passageway 110 (see FIG. 1) provided in the worksite 100 is shown. In embodiments, the method 2400 is implemented by the exemplary system 105 of FIG. 1 including the controller 125 of FIG. 4 and/or the remote sensing system 120 (see FIG. 1). At 2405, the controller 125 or the machine ECU 2310 receives at least one input from the remote sensing system 120. The remote sensing system 120 is configured to monitor the environment E (see FIG. 1) of the passageway 110 in front of and along the direction of movement M (see FIG. 1) of the machine 115, detect a presence of an obstacle in the monitored environment E, and detect a proximity of at least one lateral side, for example, L1, L2 (see FIG. 1) of the machine 115 to at least one side wall, for example, S1, S2 (see FIG. 1) of the passageway 110. At 2410, the controller 125 or the machine ECU 2310 monitors a current speed of the machine 115 and a steering angle or a steering rate of the machine defined by the steering input device 310 (see FIG. 3) and/or the machine input device 2335 in communication with the controller 125 or the machine ECU 2310 during the movement of the machine 115. At 2415, the controller 125 or the machine ECU 2310 determines an estimated distance (e.g. the stopping distance 715-2 (see FIG. 7) the machine 115 is expected to travel after a braking action is performed to bring the machine 115 to a halt based on the monitored current speed. At 2420, the controller 125 or the machine ECU 2310 determines an actual and/or an estimated clearance, for example, C1, C2, C3, C4, C5, C6 (see FIGS. 5 and 6) between the at least one lateral side, for example, L1, L2 of the machine 115 with the at least one side wall, for example, S1, S2 of the passageway 110 based on the detected proximity by the remote sensing system 120, and/or the monitored steering angle or steering rate of the machine 115. At 2425, the controller 125 or the machine ECU 2310 creates at least one virtual safety zone, for example, 700 (see FIG. 7) that dynamically extends longitudinally along the direction of movement M of the machine 115 and laterally from each lateral side, for example, L1, L2 of the machine 115 in real-time based on the monitored environment E by the remote sensing system 120, the monitored current speed, the estimated or stopping distance, for example, 715-2 and the determined actual and/or estimated clearance, for example, C1, C2, C3, C4, C5, C6. The at least one virtual safety zone, for example, 700 extends longitudinally along the length L of the machine 115 and up to the determined stopping distance, for example, 715-2 or beyond the determined stopping distance, for example, 715-2 and up to a maximum detected distance, for example, 720-2 (see FIG. 7) in the passageway 110 by the remote sensing system 120. The lateral extension, for example, B (see FIG. 7) of the at least one virtual safety zone, for example, 700 dynamically varies based on the estimated clearance, for example, C1, C2, C3, C4, C5, C6. At 2430, the controller 125 or the machine ECU 2310 performs at least one action upon detection of at least one incursion or obstacle in the at least one virtual safety zone, for example, 700 and/or when the estimated clearance, for example, C1, C2, C3, C4, C5, C6 is less than at least one threshold clearance, for example, TC1, TC2 (see FIGS. 14 and 15).

It will be apparent in view of the above that the system 105, the controller 125, and the method 2400 of the present disclosure help safe and controlled movement of the exemplary machine 115 of FIG. 2 within the passageway 110 provided within the worksite 100. For example, the system 105, the controller 125, and the method 2400 of the present disclosure enable creation of dynamically varying virtual safety zone(s) 700 including the zones, for example, 705, 710, 715, 720 (see FIG. 7) around the machine 115 defined based on, for example, the current speed of the machine 115, the determined stopping distance, for example, 715-2 (see FIG. 7) of the machine 115 and/or the determined proximity of the machine 115 to the side wall(s), for example, S1, S2 (see FIG. 1) of the passageway 110. In response to detection of any incursion and/or the obstacle(s) in any one of the safety zone(s) 700 including the zones, for example, 705, 710, 715, 720, the system 105, the controller 125, and the method 2400 of the present disclosure ensure that preventive actions including, but not limited to, providing the alerts/alarms or the visual indication(s), for example, 1205, 1405, 1505 (see FIGS. 12-15) corresponding to the determined proximity of the machine 115 to the side wall(s), for example, S1, S2, minimizing and/or limiting current speed of the machine 115, initiating braking action, and/or halting the machine 115 is performed in a timely manner. Further, by performing the preventive actions, the system 105, the controller 125, and the method 2400 of the present disclosure also ensure that machine 115 halts within the stopping distance, for example, 715-2, at all times and/or at a safe distance from any obstacle present in the safety zone(s), for example, 720. Thereby, the system 105, the controller 125, and the method 2400 of the present disclosure help mitigate collision of the exemplary machine 115 with the side wall(s), for example, S1, S2 and/or the obstacle(s) within the passageway 110 of the worksite 100.

Unless explicitly stated, the use of the singular to describe a component, structure, or operation does not exclude the use of plural such components, structures, or operations or their equivalents. The use of the terms “a” and “an” and “the” and “at least one” or the term “one or more,” and similar references herein are to be construed to cover both the singular and the plural, unless otherwise indicated herein. The use of the term “at least one” followed by a list of one or more items (for example, “at least one of A and B” or one or more of A and B”) is to be construed to mean one item selected from the listed items (A or B) or any combination of two or more of the listed items (A and B; A, A and B; or A, B and B), unless otherwise indicated herein. Similarly, as used herein, the word “or” refers to any possible permutation of a set of items. For example, the phrase “A, B, or C” refers to at least one of A, B, C, or any combination thereof, such as any of: A; B; C; A and B; A and C; B and C; A, B, and C; or multiple of any item such as A and A; B, B, and C; A, A, B, C, and C; etc.

It will be apparent to those skilled in the art that various modifications and variations can be made to the method and/or system of the present disclosure without departing from the scope of the disclosure. Other embodiments will be apparent to those skilled in the art from consideration of the specification and practice of the method and/or system disclosed herein. It is intended that the specification and examples be considered as exemplary only, with a true scope of the disclosure being indicated by the following claims and their equivalent.

What is claimed is:

1. A system for mitigating machine collision in a passageway, the system comprising:
a machine configured to operate in the passageway; at least one remote sensing system configured to:
monitor an environment of the passageway in front of and along the direction of movement of the machine, and
detect a presence of an obstacle in the monitored environment, and
detect a proximity of at least one lateral side of the machine to
at least one side wall of the passageway; and
a controller in communication with the machine and configured to control a movement of the machine in the passageway, wherein the controller is configured to:
monitor a current speed of the machine and a steering angle or a steering rate of the machine defined by an input device in communication with the controller during the movement of the machine; determine an estimated distance the machine is expected to
travel after a braking action is performed to bring the machine to a halt based on the monitored current speed;
determine an estimated clearance between the at least one lateral side of the machine with the at least one side wall of the passageway based on the detected proximity by the remote sensing system, the monitored steering angle or steering rate of the machine, or a combination thereof;
create at least one virtual safety zone that dynamically extends longitudinally along the direction of movement of the machine and laterally from each lateral side of the machine in real-time based on the monitored environment by the remote sensing system, the monitored current speed, the estimated distance, and the estimated clearance,
wherein the at least one virtual safety zone extends longitudinally along a length of the machine and up to the estimated distance or beyond the estimated distance and up to a maximum detected distance in the passageway by the remote sensing system, and wherein the lateral extension of the at least one virtual safety zone dynamically varies based on the estimated clearance; and
perform at least one action when:
the remote sensing system detects the obstacle in the at least one virtual safety zone,
the estimated clearance is less than a threshold clearance,
or any combination thereof.

2. The system of claim 1, wherein the at least one virtual safety zone corresponds to a plurality of virtual safety zones comprising:
a first virtual safety zone extending longitudinally along a length of the
machine,
a second virtual safety zone extending longitudinally from the machine
up to a threshold buffer distance,
a third virtual safety zone extending longitudinally from the threshold buffer distance ahead of the machine up to the estimated distance, and
a fourth virtual safety zone extending beyond the estimated distance and up to a maximum detected distance in the passageway by the remote sensing system.

3. The system of claim 2, wherein the controller is configured to perform the at least one action corresponding to:
minimizing the monitored current speed of the machine, limiting the monitored current speed of the machine to a threshold speed, halting the machine, or a combination thereof when the remote sensing system detects the obstacle in the fourth virtual safety zone.

4. The system of claim 1, wherein the controller is configured to detect, via the remote sensing system, an incursion along at least one side of the lateral extension of the at least one virtual safety zone and perform the at least one action corresponding to minimizing the monitored current speed of the machine, limiting the monitored current speed of the machine to a threshold speed, halting the machine, or a combination thereof.

5. The system of claim 1, wherein the controller is configured to perform the at least one action corresponding to:
providing, via an output device, an alert or warning prior to the at least one lateral side of the machine approaching the threshold clearance with the at least one side wall,
modifying the monitored steering rate or steering angle of the machine, or
a combination thereof when the estimated clearance is less than a
predefined threshold.

6. The system of claim 1, wherein the controller is configured to:
determine an actual clearance of the at least one lateral side of the machine with the at least one side wall of the passageway based on the detected proximity by the remote sensing system; and
halt the machine when the determined actual clearance is less than the threshold clearance.

7. The system of claim 1, wherein the controller is configured to:
predict a change in the estimated clearance, a rate of change of the estimated clearance, or a combination thereof between the machine and the at least one side wall based on the monitored environment, the detected proximity of the at least one side wall, or a combination thereof in front of and along the direction of movement of the machine; and
perform the at least one action based on the predicted change, the predicted rate of change, or the combination thereof in the estimated clearance.

8. The system of claim 7, wherein the lateral extension of the at least one virtual safety zone:
dynamically increases along the at least one lateral side of the machine when the predicted change or the predicted rate of change is indicative of a decrease in the estimated clearance between the at least one side of the machine and the at least one side wall adjacent of the at least one side of the machine,
dynamically decreases along the at least one lateral side of the machine when the predicted change or the predicted rate of change is indicative of an increase in the estimated clearance between the at least one side of the machine and the at least one side wall adjacent of the at least one side of the machine, and remains equally distributed along both lateral sides of the machine when
the predicted change or the predicted rate of change is nil, proximate, or equal to the estimated clearance between the lateral sides of the machine and adjacent side walls of the passageway respectively.

9. The system of claim 1, wherein the lateral extension of the at least one virtual safety zone encompasses the machine.

10. The system of claim 1, wherein
the remote sensing system corresponds to a Light Detection and Ranging (LiDAR) or a Laser Detection and Ranging (LADAR) system and is mounted or retrofitted atop the machine.

11. A controller for mitigating machine collision in a passageway, the controller comprising:
a processor; and
a memory for storing instructions that, when executed by the processor, causes the processor to:
receive at least one input from a remote sensing system of a machine, wherein the at least one remote sensing system configured to:
monitor an environment of the passageway in front of and along the direction of movement of the machine, and
and
detect a presence of an obstacle in the monitored environment,
detect a proximity of at least one lateral side of the machine to
at least one side wall of the passageway;
monitor a current speed of the machine and a steering angle or a steering rate of the machine defined by an input device in communication with the processor during the movement of the machine;
determine an estimated distance the machine is expected to travel after a braking action is performed to bring the machine to a halt based on the monitored current speed;
determine an estimated clearance between the at least one lateral side of the machine with the at least one side wall of the passageway based on the detected proximity by the remote sensing system, the monitored steering angle or steering rate of the machine, or a combination thereof;
create at least one virtual safety zone that dynamically extends longitudinally along the direction of movement of the machine and laterally from each lateral side of the machine in real-time based on the monitored environment by the remote sensing system, the monitored current speed, the estimated distance, and the estimated clearance, wherein the at least one virtual safety zone extends longitudinally along a length of the machine and up to the estimated distance or beyond the estimated distance and up to a maximum detected distance in the passageway by the remote sensing system, and wherein the lateral extension of the at least one virtual safety zone dynamically varies based on the estimated clearance; and
perform at least one action when:
the remote sensing system detects an obstacle in the at least one virtual safety zone and the at least one received input is indicative of the detected obstacle,
the estimated clearance is less than a threshold clearance, or any combination thereof.

12. A method for mitigating machine collision in a passageway, the method comprising:
receiving, via a controller, at least one input from a remote sensing system of a machine, wherein the at least one input comprises:
a monitored environment of the passageway in front of and along the direction of movement of the machine;
an indication of a presence of an obstacle in the monitored environment, a proximity of at least one lateral side of the machine to at least one side
wall of the passageway, or
any combination thereof;
monitoring, via the controller, a current speed of the machine and a steering angle or a steering rate of the machine defined by an input device in communication with the controller during the movement of the machine;
determining, via the controller, an estimated distance the machine is expected to travel after a braking action is performed to bring the machine to a halt based on the monitored current speed;
determining, via the controller, an estimated clearance between the at least one lateral side of the machine with the at least one side wall of the passageway based on the detected proximity by the remote sensing system, the monitored steering angle or steering rate of the machine, or a combination thereof;
creating, via the controller, at least one virtual safety zone that dynamically extends longitudinally along the direction of movement of the machine and laterally from each lateral side of the machine in real-time based on the monitored environment by the remote sensing system, the monitored current speed, the estimated distance, and the estimated clearance, wherein the at least one virtual safety zone extends longitudinally along a length of the machine and up to the estimated distance or beyond the estimated distance and up to a maximum detected distance in the passageway by the remote sensing system, and wherein the lateral extension of the at least one virtual safety zone dynamically varies based on the estimated clearance; and
performing, via the controller, at least one action when:
the remote sensing system detects an obstacle in the at least one safety zone and the at least one received input is indicative of the detected obstacle,
the estimated clearance is less than a threshold clearance, or any combination thereof.

13. The method of claim 12, wherein
the at least one virtual safety zone corresponds to a plurality of virtual safety zones comprising:
a first virtual safety zone extending longitudinally along a length of the
machine,
a second virtual safety zone extending longitudinally from the machine
up to a threshold buffer distance,
a third virtual safety zone extending longitudinally from the threshold buffer distance ahead of the machine up to the estimated distance, and
a fourth virtual safety zone extending beyond the estimated distance and up to a maximum detected distance in the passageway by the remote sensing system.

14. The method of claim 13, comprising:
minimizing the monitored current speed of the machine, limiting the monitored current speed of the machine to a threshold speed, halting the machine, or a combination thereof when the remote sensing system detects the obstacle in the fourth virtual safety zone.

15. The method of claim 12, comprising:
detecting, via the remote sensing system, an incursion along at least one side of the lateral extension of the at least one virtual safety zone; and
performing the at least one action corresponding to minimizing the monitored current speed of the machine, limiting the monitored current speed of the machine to a threshold speed, halting the machine, or a combination thereof.

16. The method of claim 12, comprising:
providing, via an output device, an alert or warning prior to the at least one lateral side of the machine approaching the threshold clearance with the at least one side wall,
modifying the monitored steering rate or steering angle of the machine, or
a combination thereof when the estimated clearance is less than the
threshold clearance.

17. The method of claim 12, comprising:
determining an actual clearance of the at least one lateral side of the machine with the at least one side wall of the passageway based on the detected proximity by the remote sensing system; and
halting the machine when the determined actual clearance is less than the threshold clearance.

18. The method of claim 12, comprising:
predicting a change in the estimated clearance, a rate of change of the estimated clearance, or a combination thereof between the machine and the at least one side wall based on the monitored environment, the detected proximity of the at least one side wall, or a combination thereof in front of and along the direction of movement of the machine; and
performing the at least one action based on the predicted change, the predicted rate of change, or the combination thereof in the estimated clearance.

19. The method of claim 18, wherein the lateral extension of the at least one virtual safety zone:
dynamically increases along the at least one lateral side of the machine when the predicted change or the predicted rate of change is indicative of a decrease in the estimated clearance between the at least one side of the machine and the at least one side wall adjacent of the at least one side of the machine,
dynamically decreases along the at least one lateral side of the machine when the predicted change or the predicted rate of change is indicative of an
increase in the estimated clearance between the at least one side of the machine and the at least one side wall adjacent of the at least one side of the machine, and
remains equally distributed along both lateral sides of the machine when the predicted change or the predicted rate of change is nil, proximate, or equal to the estimated clearance between the lateral sides of the machine and adjacent side walls of the passageway respectively.

20. The method of claim 12, wherein the lateral extension of the at least one virtual safety zone encompasses the machine.
